(19) United States
(12) Patent Application Publication
(10) Pub. No.: US 2016/0195822 A1
(43) Pub. Date: Jul. 7, 2016

(54) LITHOGRAPHIC APPARATUS, PROGRAMMABLE PATTERNING DEVICE AND LITHOGRAPHIC METHOD

(71) Applicant: ASML NETHERLANDS B.V., Veldhoven (NL)

(72) Inventor: Franciscus Johannes VAN DE KERKHOF, Eindhoven (NL)

(73) Assignee: ASML Netherlands B.V., Veldhoven (NL)

(21) Appl. No.: 14/911,929

(22) PCT Filed: Jul. 11, 2014
(86) PCT No.: PCT/EP2014/064923

§ 371 Date: Feb. 12, 2016

Related U.S. Application Data
(60) Provisional application No. 61/866,777, filed on Aug. 16, 2013.

(51) Int. Cl. G03F 7/20

(52) U.S. Cl. CPC G03F 7/70716

(57) ABSTRACT

A lithographic apparatus and programmable patterning device is disclosed that includes a modulator configured to expose an exposure area of the substrate to a plurality of beams modulated according to a desired pattern and a projection system configured to project the modulated beams onto the substrate. The modulator includes a plurality of VECSELs or VCSELs. The projection system may include a zone plate array that is oscillated in a Lissajous pattern. The zone plate array may include lenses arranged in a two-dimensional array where the lenses are arranged in a triangular layout. A lithographic system may include a plurality of the lithographic apparatuses, at least one lithographic apparatus being arranged above another lithographic apparatus.

### CROSS-REFERENCE TO RELATED APPLICATIONS

This application claims the benefit of U.S. provisional application 61/866,777, which was filed on Aug. 16, 2013 and which is incorporated herein in its entirety by reference.

### FIELD

The present invention relates to a lithographic apparatus, a programmable patterning device, and a device manufacturing method.

### BACKGROUND

A lithographic apparatus is a machine that applies a desired pattern onto a substrate or part of a substrate. A lithographic apparatus may be used, for example, in the manufacture of integrated circuits (ICs), flat panel displays and other devices or structures having fine features. In a conventional lithographic apparatus, a patterning device, which may be referred to as a mask or a reticle, may be used to generate a circuit pattern corresponding to an individual layer of the IC, flat panel display, or other device). This pattern may transferred on (part of) the substrate (e.g. silicon wafer or a glass plate), e.g. via imaging onto a layer of radiation-sensitive material (resist) provided on the substrate.

Instead of a circuit pattern, the patterning device may be used to generate other patterns, for example a color filter pattern, or a matrix of dots. Instead of a conventional mask, the patterning device may comprise a patterning array that comprises an array of individually controllable elements that generate the circuit or other applicable pattern. An advantage of such a “maskless” system compared to a conventional mask-based system is that the pattern can be provided and/or changed more quickly and for less cost.

Thus, a maskless system includes programmable patterning device (e.g., a spatial light modulator, a contrast device, etc.). The programmable patterning device is programmed (e.g., electronically or optically) to form the desired patterned beam using the array of individually controllable elements. Types of programmable patterning devices include micro-mirror arrays, liquid crystal display (LCD) arrays, grating light valve arrays, and the like.

### SUMMARY

It is desirable, for example, to provide a flexible, low-cost lithography apparatus that includes a programmable patterning device.

In an embodiment, there is provided a lithographic apparatus comprising: a substrate holder constructed to hold a substrate; a modulator configured to expose an exposure area of the substrate to a plurality of beams modulated according to a desired pattern, the modulator comprising a plurality of VECSELs or VCSELs to provide the plurality of beams; and a projection system configured to project the modulated beams onto the substrate.

In an embodiment, there is provided a programmable patterning device, comprising: a plurality of VECSELs or VCSELs to provide a plurality of beams modulated according to a desired pattern; and an array of lenses to receive the plurality of beams.

In an embodiment, there is provided a lithographic system, comprising a plurality of lithographic apparatuses, at least one lithographic apparatus of the plurality of lithographic apparatuses being arranged above another lithographic apparatus of the plurality of lithographic apparatuses.

In an embodiment, there is provided a zone plate array arrangement comprising lenses arranged in a two-dimensional array where the lenses are arranged in a triangular layout.

In an embodiment, there is provided a device manufacturing method, comprising: modulating a plurality of beams according to a desired pattern using a plurality of VECSELs or VCSELs that provide the plurality of beams; and projecting the modulated beams onto an exposure area of a substrate.

### BRIEF DESCRIPTION OF THE DRAWINGS

The accompanying drawings, which are incorporated herein and form a part of the specification, illustrate embodiments of the present invention and, together with the description, further serve to explain the principles of the invention and to enable a person skilled in the pertinent art to make and use the invention.

FIG. 1 depicts a schematic side view of a lithographic apparatus according to an embodiment.

FIG. 2 depicts a schematic side view of a rack arrangement of a plurality of lithographic apparatuses according to an embodiment.

FIG. 3 depicts a schematic perspective view of a lithographic apparatus according to an embodiment.

FIG. 4 depicts a schematic side view of a programmable patterning device module of a lithographic apparatus according to an embodiment.

FIG. 5 depicts a schematic bottom view of an arrangement of a plurality of modules of FIG. 4 according to an embodiment.

FIG. 6 depicts a schematic top view of a lens array arrangement of a lithographic apparatus according to an embodiment.

FIG. 7 depicts a schematic top view of a lens array arrangement of a lithographic apparatus according to an embodiment.

FIG. 8 depicts a schematic illustration of the radiation projection of a lithographic apparatus according to an embodiment.

FIGS. 9(A)-(C) depict a schematic illustration of the radiation projection of a lithographic apparatus according to an embodiment.

FIG. 10 depicts a schematic perspective view of a positioning device of a lithographic apparatus according to an embodiment.

FIG. 11 shows schematically how an entire substrate may be exposed in a single scan, by using a plurality of optical engines, each optical engine comprising one or more individually addressable elements.

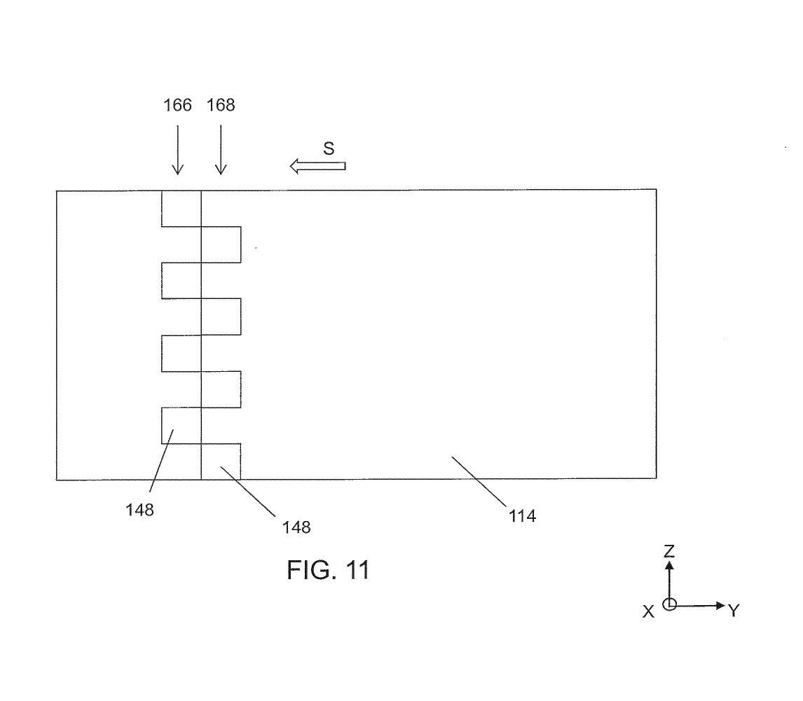

FIG. 12 depicts a schematic of the image data path of a lithographic apparatus according to an embodiment.

FIG. 13 depicts a schematic top view of a lithographic apparatus according to an embodiment.

FIG. 14 depicts a schematic top view of a lithographic apparatus according to an embodiment.

One or more embodiments of the present invention will now be described with reference to the accompanying drawings. In the drawings, like reference numbers may indicate identical or functionally similar elements.

### DETAILED DESCRIPTION

One or more embodiments of a maskless lithographic apparatus, a maskless lithographic method, a programmable patterning device and other apparatus, articles of manufacture and methods are described herein. In an embodiment, a low cost and/or flexible maskless lithographic apparatus is provided. As it is maskless, no conventional mask is needed to expose, for example, ICs or flat panel displays. Similarly, one or more rings are not needed for packaging applications; the programmable patterning device can provide digital edge-processing “rings” for packaging applications to avoid edge projection. Maskless (digital patterning) can enable use with flexible substrates.

In an embodiment, the lithographic apparatus is capable of non-critical or critical applications. In an embodiment, the lithographic apparatus is capable of ≦90 nm resolution, ≦65 nm resolution, ≦45 nm resolution, ≦32 nm resolution, ≦22 nm resolution, ≦14 nm resolution, ≦10 nm resolution, ≦7 nm resolution, or ≦5 nm resolution. In an embodiment, the lithographic apparatus is capable of ˜0.1-50 μm resolution. In an embodiment, the lithographic apparatus is capable of ≦10 nm overlay, ≦8 nm overlay, ≦5 nm overlay, ≦3 nm overlay, ≦2 nm overlay or ≦1 nm overlay. These overlay and resolution values may be regardless of substrate size and material.

In an embodiment, the lithographic apparatus is highly flexible. In an embodiment, the lithographic apparatus is scalable to substrates of different sizes, types and characteristics. In an embodiment, the lithographic apparatus has a virtually unlimited field size. Thus, the lithographic apparatus can enable multiple applications (e.g., IC, flat panel display, packaging, etc.) with a single lithographic apparatus or using multiple lithographic apparatus using a largely common lithographic apparatus platform. In an embodiment, the lithographic apparatus allows automated job generation to provide for flexible manufacture.

In an embodiment, the lithographic apparatus is low cost. In an embodiment, only, or mostly, common off-the-shelf components are used (e.g., radiation emitting lasers, a simple movable substrate holder, and a lens array). In an embodiment, pixel-grid imaging is used to enable simple projection optics. In an embodiment, a substrate holder having a single scan direction is used to reduce cost and/or reduce complexity.

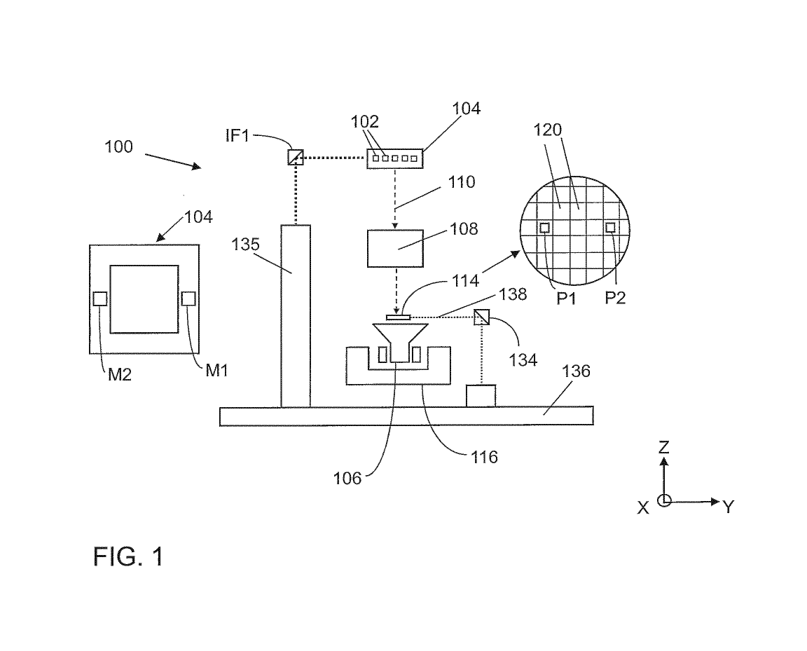

FIG. 1 schematically depicts a lithographic projection apparatus 100 according to an embodiment. Apparatus 100 includes a patterning device 104, an object holder 106 (e.g., an object table, for instance a substrate table), and a projection system 108.

In an embodiment, the patterning device 104 comprises a plurality of individually controllable elements 102 to modulate radiation to apply a pattern to beam 110. In an embodiment, the position of the plurality of individually controllable elements 102, when used to provide radiation, can be fixed relative to frame 135 or at least a part of projection system 108. In an arrangement, a plurality of individually controllable elements 102 may be connected to a positioning device (not shown) to accurately position one or more of them in accordance with certain parameters (e.g., with respect to at least part of the projection system 108).

In an embodiment, the patterning device 104 is a self-emissive contrast device. Such a patterning device 104 obviates the need for a radiation system, which can reduce, for example, cost and size of the lithographic apparatus. For example, each of the individually controllable elements 102 may be a radiation emitting diode, such as a light emitting diode (LED), an organic LED (OLED), a polymer LED (PLED), or a laser diode (e.g., solid state laser diode).

In an embodiment, each of the individually controllable elements 102 is a vertical-external-cavity surface-emitting laser (VECSEL) or a vertical-cavity surface-emitting laser (VCSEL). VCSELs and VECSELs can offer excellent spectral purity, high power and good beam quality. In an embodiment, a VECSEL or VCSEL may output 772 or 774 nm radiation. However, the radiation provided on the substrate may be different than output by the VECSEL or VCSEL. In an embodiment, the VECSEL or VCSEL radiation is converted to about 248 nm, about 193 nm, about 157 nm, or about 128 nm. In an embodiment, an array of VECSELs or VCSELs may be provided. For example, the array may be provided on a single substrate (e.g., a GaAs wafer). In an embodiment, the array is two-dimensional. In an embodiment, the array may comprise 256 VECSELs or VCSELs.

In an embodiment, a radiation output of the VECSEL or VCSEL is frequency multiplied to, e.g., about 248 nm, about 193 nm, about 157 nm, or about 128 nm. In embodiment, the radiation output is frequency quadrupled. In an embodiment, the radiation is frequency quadrupled using two stages of frequency doubling. In an embodiment, the frequency multiplication is done using BBO (β-BaB₂O₄), periodically poled lithium niobate (PPLN) and/or KBBF (KBe₂BO₃F₂) non-linear optics. In an embodiment, the frequency quadrupling is done using BBO or PPLN in a first stage and KBBF in a second stage. In an embodiment, the conversion efficiency may be about 1%. In an embodiment, for frequency quadrupling using two stages of frequency doubling, the first stage may have about 20% conversion efficiency and the second stage may have about 5% conversion efficiency. In an embodiment, frequency doubling may be performed intra-cavity. For example, the first stage of frequency doubling may be intra-cavity frequency doubling using BBO or PPLN

In an embodiment, a dose of up to 20 mJ/cm² may be provided at substrate level. This dose level may be a factor of 100 or more than required. Such dose level may afford the use of a non-amplified resist, which may reduce line edge roughness and/or relaxing post processing requirements. In an embodiment, the VECSEL or VCSEL may produce a 3 mW power beam. In an embodiment, that beam may have 4 μW power at substrate level to provide, for example, an exposure dose of up to 20 mJ/cm².

In an embodiment, the beam intensity could be achieved by applying ‘pulsed’ operation on the VECSEL or VCSEL array and the use of a 10× beam reducer which further increases the beam intensity by a factor 100 after wavelength doubling and collimation is performed. Therefore, with an initial dose increased by a factor 100 and a second stage wavelength doubling conversion at 0.75, the dose level of a factor of 100 or more may be provided. With the efficiency of a zone plate array at around 40%, there should be around a factor of 30 left at substrate level.

A potential improvement could be to mode lock the VECSEL or VCSEL to create short picoseconds pulses. In an embodiment, active mode locking may be used to generate pulses synchronized with the exposure frequency of 100 MHz.

In an embodiment, a titanium doped sapphire crystal based regenerative amplifier which is externally pumped by a pump laser may be used to get the pulses up to a desired energy level. A YAG pump laser could be placed in the “outer” world (as described hereafter) and the radiation provided therefrom guided by a beam guide to the VECSELs or VCSELs. The energy level could be further enhanced by cavity dumping the dose and q-switching using a Pockels or Kerr cell to release the desired dose in a femtosecond timeframe with the same synchronization of 100 Mhz.

In an embodiment, the start and end moment of the radiation impulses from the VCSELs or VECSELs should be centralized within the 10 ns pixel exposure timeframe. This helps to prevent critical dimension uniformity (CDU) loss.

In an embodiment, the array of VECSELs or VCSELs may be tuned for improved or maximum dose performance. For example, the apertures of the VECSEL or VCSEL may be increased. In an embodiment, the final switching controller that controls the output (e.g., turning “on” or “off”) of the VECSEL or VCSEL may be integrated with the VECSEL or VCSEL, e.g., integrated on the same (GaAs) substrate as the VECSEL or VCSEL. This can allow increased or maximum rise and fall times of the applied impulse. Additionally or alternatively, this integration may simplify the connections between the VECSEL or VCSEL and the wave generator device as described hereafter.

In an embodiment, the self-emissive contrast device comprises more individually addressable elements 102 than needed to allow a “redundant” individually controllable element 102 to be used if another individually controllable element 102 fails to operate or doesn't operate properly. In addition or alternatively, extra movable individually addressable elements may have an advantage for controlling thermal load on the individually addressable elements as a first set of individually addressable elements may be used for a certain period and then a second set is used for another period while the first set cools.

In an embodiment, the individually addressable elements 102 are embedded in a material comprising low thermal conductivity. For example, the material may be a ceramic e.g., cordierite or a cordierite-based ceramic and/or Zerodur ceramic. In an embodiment, the individually addressable elements 102 are embedded in a material comprising high thermal conductivity, for instance a metal, e.g. a metal of relatively light weight, for instance aluminum or titanium, so that the heat can be conducted away and then removed/cooled.

In an embodiment, the array of the individually addressable elements 102 may comprise a temperature control arrangement. In an embodiment, the VECSELs or VCSELs are provided a cooling system. For example, an array of the individually addressable elements 102 may have a fluid (e.g., liquid) conducting channel to transport cooling fluid on, near or through the array to cool the array. The channel may be connected to an appropriate heat exchanger and pump to circulate fluid through the channel. A supply and return connected between the channel and heat exchanger and pump can facilitate circulation and temperature control of the fluid. A sensor may be provided in, on or near the array, to measure a parameter of the array, which measurement may be used to control, e.g., the temperature of the fluid flow provided by the heat exchanger and pump. In an embodiment, sensor may measure the expansion and/or contraction of the array body, which measurement may be used to control the temperature of the fluid flow provided by the heat exchanger and pump. Such expansion and/or contraction may be a proxy for temperature. In an embodiment, the sensor may be integrated with the array and/or may be separate from the array.

The lithographic apparatus 100 comprises an object holder 106. In this embodiment, the object holder comprises an object table 106 to hold a substrate 114 (e.g., a resist-coated silicon wafer or glass substrate). The object table 106 may be movable and be connected to a positioning device 116 to accurately position substrate 114 in accordance with certain parameters. For example, positioning device 116 may accurately position substrate 114 with respect to projection system 108 and/or the patterning device 104. In embodiment, the positioning device may comprise one or more piezo actuators. In an embodiment, the positioning device 116 may scan the substrate at a speed of about 1 mm/s, of more than or equal to 2 mm/s, of more than or equal to 5 mm/s, of more than or equal to about 10 mm/s. In an embodiment, the positioning device 116 may scan the substrate at a speed of less than or equal to about 150 mm/s, less than or equal to about 100 mm/s, less than or equal to about 50 mm/s, less than or equal to about 10 mm/s, or less than or equal to about 5 mm/s.

In an embodiment, movement of object table 106 may be realized with a positioning device 116 comprising a long-stroke module (coarse positioning) and optionally a short-stroke module (fine positioning), which are not explicitly depicted in FIG. 1. In an embodiment, the apparatus is absent at least a short stroke module to move the object table 106. A similar system may be used to position the individually controllable elements 102 and/or at least part of the projection system 104. Beam 110 may alternatively/additionally be moveable, while the object table 106 and/or the individually controllable elements 102 may have a fixed position to provide the required relative movement. In an embodiment, which may e.g. be applicable in the manufacture of flat panel displays, the object table 106 may be stationary and positioning device 116 is configured to move substrate 114 relative to (e.g., over) object table 106. For example, the object table 106 may be provided with a system to scan the substrate 114 across it at a substantially constant velocity. Where this is done, object table 106 may be provided with a multitude of openings on a flat uppermost surface, gas being fed through the openings to provide a gas cushion which is capable of supporting substrate 114. This is conventionally referred to as a gas bearing arrangement. Substrate 114 is moved over object table 106 using one or more actuators (not shown), which are capable of accurately positioning substrate 114 with respect to the path of beam 110. Alternatively, substrate 114 may be moved with respect to the object table 106 by selectively starting and stopping the passage of gas through the openings. In an embodiment, the object holder 106 can be a roll system onto which a substrate is rolled and positioning device 116 may be a motor to turn the roll system to provide the substrate onto an object table 106.

Projection system 108 (e.g., a quartz and/or CaF₂ lens system) can be used to project the patterned beam modulated by the individually controllable elements 102 onto a target portion 120 (e.g., one or more dies) of substrate 114. In an embodiment, projection system 108 may project image the pattern provided by the plurality of individually controllable elements 102 such that the pattern is coherently formed on the substrate 114. In an embodiment, projection system 108 may project images of secondary sources for which the elements of the plurality of individually controllable elements 102 act as shutters.

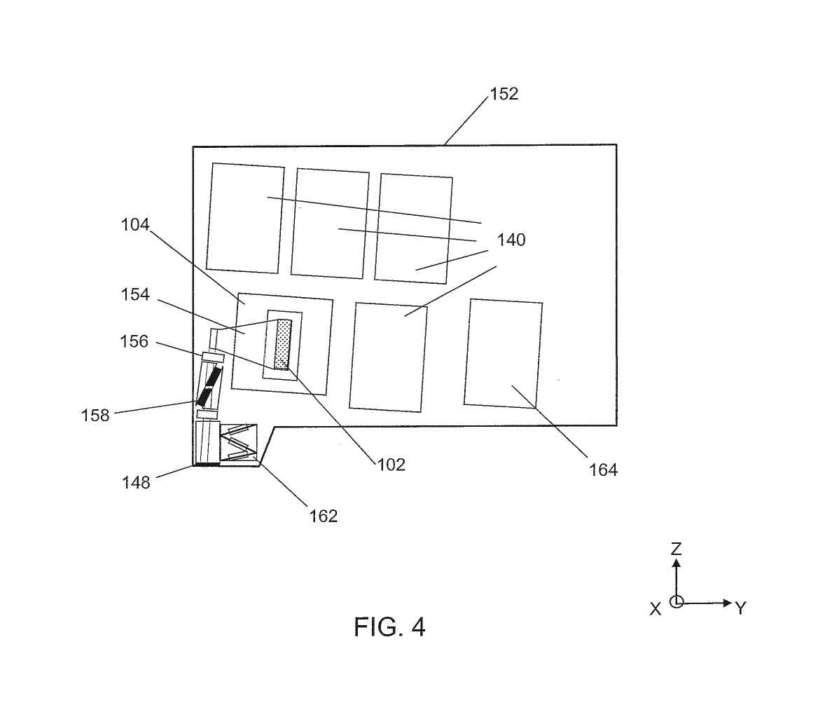

In this respect, the projection system may comprise a focusing element 148 (see, e.g., FIGS. 4, 6 and 7), or a plurality of focusing elements (herein referred to generically as a lens array) e.g., a micro-lens array (known as an MLA), a zone plate array or a Fresnel lens array, e.g. to form the secondary sources and to image spots onto the substrate 114. Thus, in an embodiment, the exposure is based on an array of Huygens-Fresnel diffractive lenses. This type of exposure involves incoherent addition of on-axis focus spots from an array of diffractive optical elements, such as arrange on a zone plate. The zone plate may have a high numerical aperture values. The exposure method may produce patterns where the K1 factor is below 0.3 with sufficient contrast in dense patterns. In embodiment, a plurality of plasmonic lenses may be used to provide near field imaging beyond the K1 factor and down to, e.g., 5 nm resolution. While the disclosure herein will focus on a zone plate array as the focusing element 148, the focusing element 148 may be a different arrangement.

In an embodiment, the lens array (e.g., MLA) comprises at least 10 focusing elements, at least 100 focusing elements, at least 256 focusing elements, at least 300 focusing elements, at least 400 focusing elements, or at least 1000 focusing elements. In an embodiment, the number of individually controllable elements in the patterning device is equal to or greater than the number of focusing elements in the lens array. In an embodiment, the lens array comprises a focusing element that is optically associated with one or more of the individually controllable elements in the array of individually controllable elements, e.g. with only one of the individually controllable elements in the array of individually controllable elements, or with 2 or more of the individually controllable elements in the array of individually controllable elements, e.g., 3 or more, 5 or more, 10 or more, or 20 or more. In an embodiment, the lens array comprises more than one focusing element (e.g. more than 100, the majority, or about all) that is optically associated with one or more of the individually controllable elements in the array of individually controllable elements.

In an embodiment, the lens array is movable. In an embodiment, the lens array is moved in the direction to and away from the substrate, e.g. with the use of one or more actuators. Being able to move the lens array to and away from the substrate allows, e.g., for focus adjustment without having to move the substrate. In an embodiment, an individual lens element in the lens array, for instance each individual lens element in the lens array, is movable in the direction to and away from the substrate (e.g. for local focus adjustments on non-flat substrates or to bring each optical column into the same focus distance). In an embodiment, as further described hereafter, the lens array may be moved orthogonal to the direction of radiation projection.

In an embodiment, the lens array comprises plastic focusing elements (which may be easy to make, e.g. injection molding, and/or affordable), where, for example, the wavelength of the radiation is greater than or equal to about 400 nm (e.g. 405 nm). In an embodiment, the wavelength of the radiation is selected from the range of about 400 nm-500 nm. In an embodiment, the lens array comprises quartz focusing elements. In an embodiment, the lens array comprises fused quartz. In an embodiment, the lens array comprises crystalline quartz instead of fused quartz. In an embodiment, the lens array has a nearly flat surface profile, e.g. have no optical elements (or parts of optical elements) sticking out above or below one or more surfaces of the plate. This may be achieved, for instance, by ensuring the zone plate array 148 is sufficiently thick (i.e. at least thicker than the height of the optical elements and positioning the optical elements such that they do not stick out) or by providing a flat cover plate over the zone plate array 148 (not shown). Ensuring one or more surfaces of the plate is substantially flat may assist in, e.g., noise reduction when the apparatus is in use.

In an embodiment, each or a plurality of the focusing elements may be an asymmetrical lens. The asymmetry may be the same for each of the plurality of focusing elements or may be different for one or more focusing elements of a plurality of focusing elements than for one or more different focusing elements of a plurality of focusing elements. An asymmetrical lens may facilitate converting an oval radiation output into a circular projected spot, or vice versa.

In an embodiment, the focusing element has a high numerical aperture (NA) that is arranged to project radiation onto the substrate out of the focal point to obtain low NA for system. A higher NA lens may be more economic, prevalent and/or better quality than an available low NA lens. In an embodiment, low NA is less than or equal to 0.3, in an embodiment 0.18 or less or 0.15 or less. Accordingly, a higher NA lens has a NA greater than the design NA for the system, for example, greater than 0.3, greater than 0.18, or greater than 0.15.

While, in an embodiment, the projection system 108 is separate from the patterning device 104, it need not be. The projection system 108 may be integral with the patterning device 108. For example, a lens array block or plate may be attached to (integral with) with a patterning device 104. In an embodiment, the lens array may be in the form of individual spatially separated lenslets, each lenslet attached to (integral with) with an individually addressable element of the patterning device 104.

Optionally, the lithographic apparatus may comprise a radiation supply system to supply radiation (e.g., ultraviolet (UV) radiation) to the plurality of individually controllable elements 102. If the patterning device is a radiation source itself, e.g. a VECSEL or VCSEL array, the lithographic apparatus may be designed without a radiation system, i.e. without a radiation source other than the patterning device itself, or at least a simplified radiation system. The radiation supply system may include a radiation source (e.g., an excimer laser) to produce the radiation for supply to or by the plurality of individually controllable elements 102. The radiation source and the lithographic apparatus 100 may be separate entities, for example when the radiation source is an excimer laser. In such cases, the radiation source is not considered to form part of the lithographic apparatus 100 and the radiation is passed from the source to the lithographic apparatus. In other cases the radiation source may be an integral part of the lithographic apparatus 100, for example when the source is a mercury lamp.

The lithographic apparatus may comprise a radiation conditioning system, which may be in addition to, or part of, a radiation supply system if the lithographic apparatus includes a radiation supply system. The radiation conditioning system includes one or more of the following elements: a radiation delivery system (e.g., suitable directing mirrors), a radiation conditioning device (e.g., a beam expander), an adjusting device to set the angular intensity distribution of the radiation (generally, at least the outer and/or inner radial extent (commonly referred to as σ-outer and σ-inner, respectively) of the intensity distribution in a pupil plane of the illuminator can be adjusted), an integrator, and/or a condenser. The radiation conditioning system may be used to condition the radiation that will be provided by, or to, the individually controllable elements 102 to have a desired uniformity and intensity distribution in its cross-section. The radiation conditioning system may be arranged to divide radiation into a plurality of sub-beams that may, for example, each be associated with one or more of the plurality of the individually controllable elements. A two-dimensional diffraction grating may, for example, be used to divide the radiation into sub-beams. In the present description, the terms “beam of radiation” and “radiation beam” encompass, but are not limited to, the situation in which the beam is comprised of a plurality of such sub-beams of radiation.

In an embodiment, the radiation source, which in an embodiment may be the plurality of individually controllable elements 102, can provide radiation that will have a wavelength at substrate level of at least 5 nm, e.g. at least 10 nm, at least 50 nm, at least 100 nm, at least 150 nm, at least 175 nm, at least 200 nm, at least 250 nm, at least 275 nm, at least 300 nm, at least 325 nm, at least 350 nm, or at least 360 nm. In an embodiment, the radiation has a wavelength of at most 450 nm, e.g. at most 425 nm, at most 375 nm, at most 360 nm, at most 325 nm, at most 275 nm, at most 250 nm, at most 225 nm, at most 200 nm, or at most 175 nm. In an embodiment, the radiation has a wavelength including 436 nm, 405 nm, 365 nm, 355 nm, 248 nm, 193 nm, 157 nm, 126 nm, and/or 13.5 nm. In an embodiment, the radiation includes a wavelength of around 193 nm. In an embodiment, the radiation includes a broad band of wavelengths, for example encompassing 365 nm, 405 nm and 436 nm. A 355 nm laser source could be used.

In operation of the lithographic apparatus 100, the patterned beam 110, after having been created by the plurality of individually controllable elements 102, passes through projection system 108, which focuses beam 110 onto a target portion 120 of the substrate 114.

With the aid of positioning device 116 (and optionally a position sensor 134 on a base 136 (e.g., an interferometric measuring device that receives an interferometric beam 138, a linear encoder or a capacitive sensor)), substrate 114 can be moved accurately, e.g., so as to position different target portions 120 in the path of beam 110. In an embodiment, a positioning device for at least part of the projection system 108 can be used to accurately move the at least part of the projection system 108 with respect to the path of beam 110, e.g., during a scan.

Although lithography apparatus 100 according to an embodiment is herein described as being for exposing a resist on a substrate, it will be appreciated that apparatus 100 may be used to project a patterned beam 110 for use in resistless lithography.

The depicted apparatus 100 can be used in one or more modes e.g.:

1. In step mode, the individually controllable elements 102 and the substrate 114 are kept essentially stationary, while an entire patterned radiation beam 110 is projected onto a target portion 120 at one go (i.e. a single static exposure). The substrate 114 is then shifted in the X- and/or Y-direction so that a different target portion 120 can be exposed to the patterned radiation beam 110. In step mode, the maximum size of the exposure field limits the size of the target portion 120 imaged in a single static exposure.

2. In scan mode, the individually controllable elements 102 and the substrate 114 are scanned synchronously while a pattern radiation beam 110 is projected onto a target portion 120 (i.e. a single dynamic exposure). The velocity and direction of the substrate relative to the individually controllable elements may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

3. In pulse mode, the individually controllable elements 102 are kept essentially stationary and the entire pattern is projected onto a target portion 120 of the substrate 114 using pulsing (e.g., provided by a pulsed radiation source or by pulsing the individually controllable elements). The substrate 114 is moved with an essentially constant speed such that the patterned beam 110 is caused to scan a line that extends across the substrate 114. The pattern provided by the individually controllable elements is updated as required between pulses and the pulses are timed such that target portions 120 are exposed at the required locations on the substrate 114. Consequently, patterned beam 110 can scan across the substrate 114 to expose the complete pattern for a strip of the substrate 114. The process is repeated until the complete substrate 114 has been exposed line by line.

4. In continuous scan mode, essentially the same as pulse mode except that the substrate 114 is scanned relative to the modulated beam of radiation B at a substantially constant speed and the pattern on the array of individually controllable elements is updated as the patterned beam 110 scans across the substrate 114 and exposes it. A substantially constant radiation source or a pulsed radiation source, synchronized to the updating of the pattern on the array of individually controllable elements may be used.

Combinations and/or variations on the above described modes of use or entirely different modes of use may also be employed.

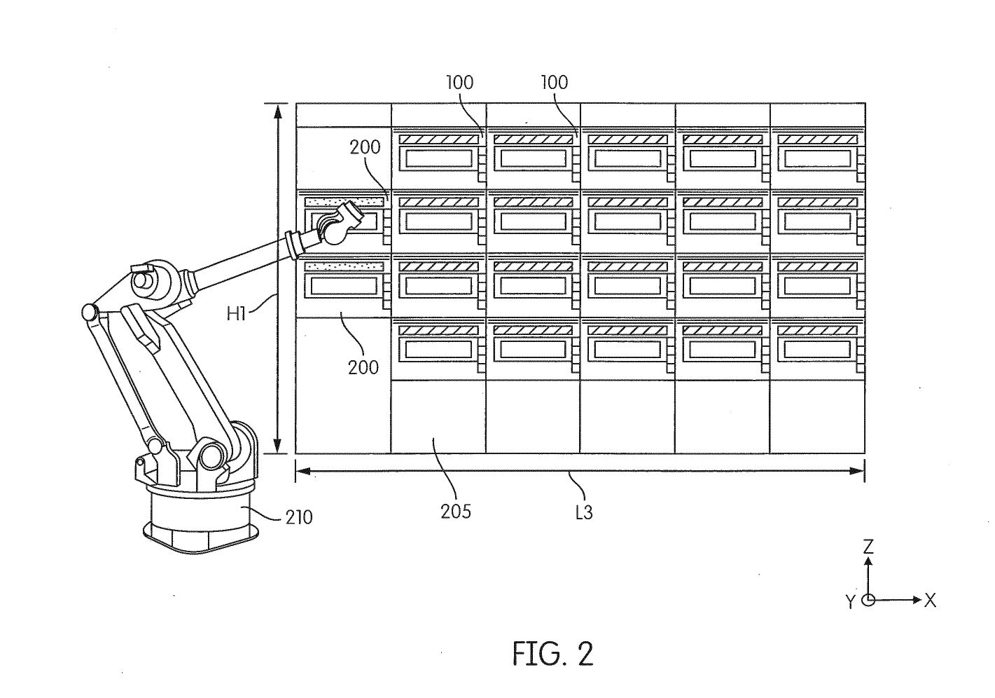

FIG. 2 depicts a schematic side view of a rack arrangement of a plurality of lithographic apparatuses according to an embodiment. As can be seen in FIG. 2, an embodiment of the invention is unique in that a plurality of lithographic apparatuses 100 are arranged in a form factor similar to a standard single lithographic apparatus using an optical mask, forming what may be called a hive; the lithographic apparatus of this embodiment is significantly smaller than a conventional lithographic apparatus using an optical mask. The design can provide scalability and/or robustness. For example, as discussed further hereafter, it can allow for separation of distinctly different tasks, such as measuring and exposing, which can allow for increased robustness and/or lower downtime due to maintenance. Additionally or alternatively, this design concept can scale for the given end use requirements, starting, perhaps, as small as 10 substrates per hour (WPH) with manual operation on a single substrate basis with a single lithographic apparatus all the way up to hundreds of WPH through fully automated processing with a plurality of lithographic apparatuses.

In an embodiment, the lithographic apparatuses are arranged in a rack 205. The rack may have a plurality of openings, each for receiving a lithographic apparatus or other apparatus. In an embodiment, the rack is in a two-dimensional arrangement such that the lithographic apparatuses may be arranged in a two-dimensional array; FIG. 2 shows a 5 wide by 4 high array of lithographic apparatuses. So, in the embodiment of FIG. 2, each lithographic apparatus rack unit may process approximately 10 substrates per hour (WPH). Accordingly, the rack in FIG. 2 may process approximately 200 WPH using 20 lithographic exposure rack units of 10 WPH each. The rack 205 will have facilities common to each of the units or to a particular unit type. For example, the rack 205 will have a power electrical system and electronics, an overall control system, a cooling system, etc.

In an embodiment, the rack may receive units other than a lithographic apparatus. For example, a rack unit may be a measurement apparatus 200. FIG. 2 depicts 2 measurement apparatuses 200. In the measurement apparatus, the to-be exposed substrate may be measured and/or aligned. For example, the measurement apparatus may receive a substrate cassette comprising the substrate and a substrate clamping plate. The plate can provide temperature stability and/or reference accuracy. The measurement apparatus may then measure one or more alignment marks on the substrate and note their relative position to the clamping plate (which may also include one or more alignment marks). In an embodiment, the measurement apparatus may map the surface height of the substrate. In an embodiment, a rack unit may be a metrology tool to measure, for example, critical dimension, line edge roughness, etc. In an embodiment, a rack unit may be unit to receive substrate cassettes for temporary storage, for exchange with a post-processing device (e.g., a track) and/or production lot collection. Other types of rack units may be provided.

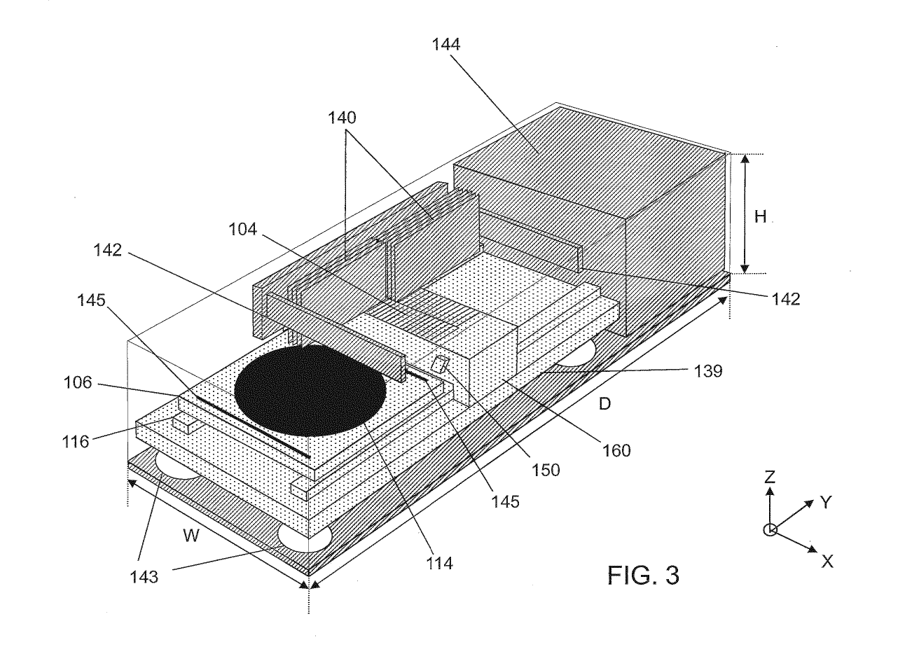

In an embodiment, each type of rack unit may be of the same size. In an embodiment, each rack unit of a same type is of the same size. In an embodiment, the height of a rack unit is smaller than its width. In an embodiment, a rack unit has a height H (see FIG. 3) of less than or equal to about 40 cm; this could allow stacking of 4 units in one rack and still allow some space above and below. In an embodiment, a rack unit is less than or equal to about 50 cm wide W (see FIG. 3). In an embodiment, a rack unit is less than or equal to about 120 cm deep D (see FIG. 3). This rack of lithographic apparatuses as disclosed may show a significant gain in terms of WPH against floor space versus traditional machines. For example, 200 WPH may be realized in an all-in volume of roughly 3 meters length L3 by 2 meters height H1 by 2 meters depth D.

In an embodiment, each opening in the rack is of a same size. In an embodiment, each opening for a same type of rack unit is of a same size. Thus, there may be one or more standard sizes for lithographic apparatus rack units, measurement apparatus rack units and other prospective units. In an embodiment, the racks may be of different sizes and with different numbers of openings (and/or different size openings) to allow mix and match configurations of rack units depending on the end use. In an embodiment, one or more of the rack units may be readily removable from the rack by being releasably clamped to the rack (by, e.g., one or more bolts).

One or more of the rack units may not be hard linked to one or more other rack units and thus may operate independently depending on the need. In an embodiment, each of the rack units operates independently. In an embodiment, a plurality of rack units operates dependently on each but independently from one or more other rack units. The rack units may individually controlled from a plant or rack host computer depending on end use requirements.

Individual rack units can be taken ‘off-line’ and taken out of the rack for maintenance or repair (or repaired while in the rack) while the rack as such only loses a limited amount of productivity depending on the number of rack units and the configuration of the rack units. Thus, a unit can be switched out of production and removed from the rack for repair, while losing only a fraction of the rack productivity.

To enable supply of substrates to the lithographic apparatus rack units, substrate loading/unloading is facilitated using a robot 210. A standard industry robot may provide sufficient adaptability for the given configuration. The robot 210 arm moves a single substrate from docking location (e.g., a rack unit, a storage location, etc.) to docking location. All robot manipulations should be well controlled and within acceleration parameters to help avoid loss of measured state during exchange. The robot itself may be readily and quickly replaced in case of malfunction. In an embodiment, two or more robots may be provided to provide redundancy and/or improved speed. In an embodiment, a robot may be shared with another rack (e.g., the robot is movable). In an embodiment, a plurality of robots is shared among a plurality of racks.

As mentioned above, the robot 210 may exchange substrates using a closed single substrate cassette where the substrate is clamped on a substrate carrier plate, which plate may control the substrate temperature stability. The internal environment of the cassette may be controlled. The plate may contain one or more reference marks (e.g., alignment marks). The substrate cassette may carry substrate process data (e.g., stored on a memory in or on the cassette). In an embodiment, exchange of the cassette between the rack units may be based on a standardized docking/exchange procedure. In an embodiment, the interface to the post-processing device and/or storage location may be adapted to handle the substrate cassette (e.g., have a same docking standard as the rack units) and may provide carrier plate clamping/releasing. The robot 210 may supply power to the substrate carrier plate electronics during the interchange.

This design concept may reduce the software complexity significantly because tasks may be separated and a ‘critical path’ is now largely absent due to the robust parallelized production method. Most of the substrate logistics can be run from a host and, by involving multiple hosts, can easily be made robust. For device image logistics one or more distributed image data hosts should be involved. Image transfer may be controlled indirectly from the fab automation host. Together with modularization of the tasks involving substrate measurement and exposure, the software may also be modularized and separated. Software may be specific for rack unit type, and perhaps rack unit version. Thus, the software may be much simpler in nature and releasing of a new version of software for one or more rack units can be done independently from one or more other rack units, provided compatibility is correctly maintained. From the perspective of the fab automation host, the rack units may be separate devices that are separately controlled over the same network. In an embodiment, a control console may not be necessary. Instead the control application may be portable and any portable device could be used for local or remote control. For example, a webserver-based service interface may be provided to handle maintenance actions and may be accessible via the fab network via, for example, a portable device (such as a tablet or laptop). The software may extend and unify the SECS interface as the standard for host as well as operator control. Based on correct, complete and consistent state logging via the SECS interface, the control application may be able to conduct desired operator interventions via the same control channel as the host. This can eliminate a lot of unnecessary functionality from the machine control software. Thus, this software simplicity and modulatory together with the cluster robustness and reduced unit complexity may allow significant reduction in mean time to repair (MTTR).

FIG. 3 depicts a schematic perspective view of a lithographic apparatus according to an embodiment for use with substrates (e.g., 300 mm or 450 mm wafers). The lithographic apparatus may be designed for about 10 WPH independent of device layout. The apparatus may be made mostly of commercial off the shelf technology. This is applicable for the image storage, the data path, the patterning devices and their associated electronics. This kind of design helps to improve or maximize the expected mean time between interrupts (MTBI). The design may allow higher productivity to 15 WPH, or 20 WPH, or 30 WPH, or perhaps higher. In an embodiment, the lithographic apparatus is designed for 193 nm (ArF) immersion lithography at the 45 nm node. This is for ease of implementation in existing fab processes, environment and infrastructure. However, to be sure, the lithographic apparatus may be designed for a different wavelength and/or node and may operate without immersion.

As shown in FIG. 3, the lithographic apparatus 100 comprises a substrate table 106 to hold a wafer 114. Associated with the substrate table 106 is a positioning device 116 to move the substrate table 106 in at least the Y-direction. Optionally, the positioning device 116 may move the substrate table 106 in the X-direction and/or Z-direction. The positioning device 116 may also rotate the substrate table 106 about the X-, Y- and/or Z-directions. Accordingly, the positioning device 116 may provide motion in up to 6 degrees of freedom. In an embodiment, the substrate table 106 provides motion only in the Y-direction, an advantage of which is lower costs and less complexity. In an embodiment, the substrate positioning device 116 is connected to a base 139 which may rest on one or more mounts 143 (e.g., three or four gas mounts).

The lithographic apparatus 100 further comprises a patterning device 104 comprising plurality of individually addressable elements 102 arranged on a frame 160. In an embodiment, the frame 160 is mounted on the base 139. While one frame 160 is shown, the lithographic apparatus may have a plurality of frames 160.

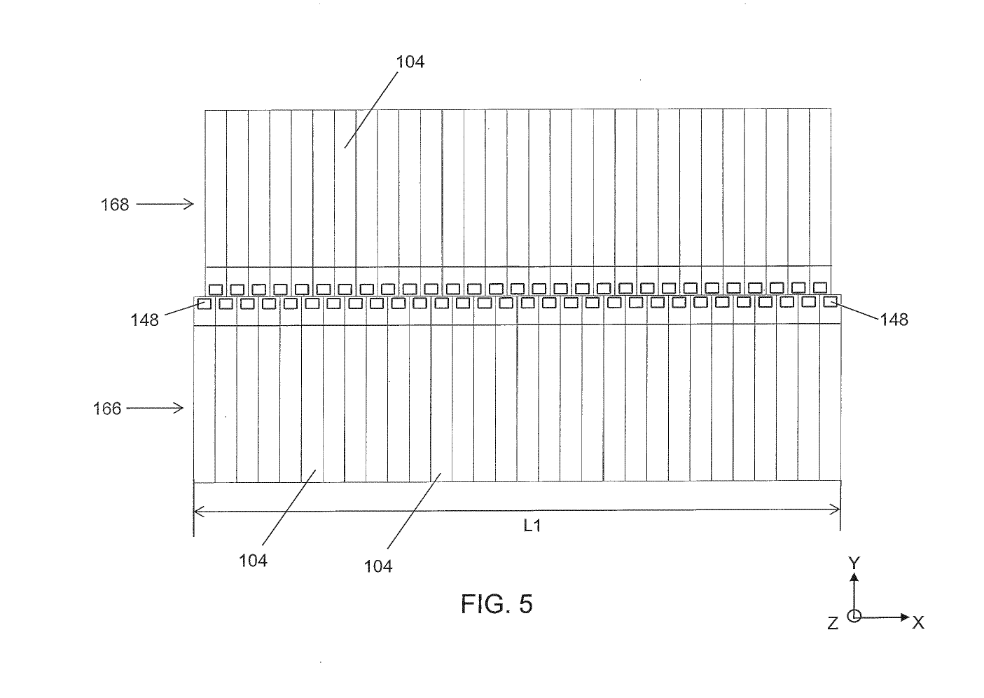

In this embodiment, there is a plurality of separate patterning devices 104, which are schematically shown by the rectangular shapes on the frame 160. In FIG. 3, only a few patterning devices 104 are shown. In an embodiment, the patterning devices 104 extend in the X-direction along the frame 160 for the cross-sectional dimension (e.g., diameter) of the substrate 114. This pattern of rectangular shapes is shown in more detail in FIG. 5.

The number of patterning devices 104 on frame 160 may depend, inter alia, on the length of the exposure region that the patterning devices 104 are intended to cover, the speed with which there is relative motion between the substrate and the beams during exposure, the spot size (i.e., cross-sectional dimension, e.g., width/diameter, of the spot projected on the substrate from an individually addressable element 102), the desired intensity each of the individually addressable elements should provide, cost considerations, the frequency with which the individually addressable elements can be turned on or off, and the desire for redundant individually addressable elements 102. In an embodiment, spot size on the substrate is 100 nanometers or less, 50 nanometers or less, 25 nanometers or less, 20 nanometers or less, 10 nanometers or less, 5 nanometers or less, or 2 nanometers or less. In an embodiment, the spot size is 1 nanometer or more, 2 nanometers or more, 5 nanometers or more, 10 nanometers or more, or 20 nanometers or more.

In an embodiment, the frame 160 is designed to allow for modularity with respect to the patterning devices 104. For example, the frame 160 may comprise a series of slots to accommodate individual patterning devices 104 similar to accommodating inkjet cartridges in a printer. The patterning devices 104 may be removably clamped onto the frame 160 and may be readily substituted for another. Each patterning device 104 may be provided to the frame 160 by a module 152 (see, e.g., FIG. 4), which is releasably connected to the frame 160.

Each of the patterning devices 104 may comprise a plurality of individually addressable elements 102. In an embodiment, each individually address element 102 is a VECSEL or VCSEL. The lithographic apparatus 100, particularly the individually addressable elements 102, may be arranged to provide pixel-grid imaging as described in more detail herein.

Each of the patterning devices 104 may include, or be associated, with its own exposure controller 140. These controllers 140 may be manufactured in a module 152 with the patterning device 104 (as shown, for example, in FIG. 4) or may be separately provided. In an embodiment, the controllers 140 are connected to a data bus 142, e.g., an optical data bus. The data bus 142 connects to an enclosure 144 comprising the image data path hardware and/or software. In an embodiment, the data path enclosure 144 is at the back of the unit to allow easy access from behind for replacement of any failing part (e.g., a solid-state drive, switch, etc.). In an embodiment, each of the controllers 140 comprises one or more wave (pulse) generators (in this case, 4) having 64 channels at 100 MHz. In an embodiment, the data bus 142 comprises a thin film ribbon loop. In an embodiment, the controllers 140 are positioned above the zone plate array 148.

In an embodiment, each module 152 may be essentially self-contained, which may allow for better subsystem reliability, lower stock and reduced obsolescence value. Thus, in an embodiment, the module 152 may comprise the patterning device 104 and its associated controller(s). Further, as discussed herein, the module 152 may comprise at least part of the projection system 108, such as a zone plate array 148 associated with the patterning device 104 of the module 152. Such a module may allow for “plug and play” replacement of a failing or failed module. Such a module may reduce spare part cost due to stock and obsolescence value. Such a module may allow for lower repair labor costs. Such a module can reduce complexity and allow simplification of the part design; the module may be mass reproduced.

In an embodiment, referring to FIG. 3, the parts hatched with diagonal lines are part of an “outer” world and the parts hatched with dots are part of an “inner” world. The “inner” world may be mechanically isolated from the “outer” world. That is the “inner” world may be substantially isolated from vibrations and forces from the “outer” world. Thus, in an embodiment, the “inner” world may comprise the substrate table 106, bearings (if any) for the substrate table 106 and the frame 160 holding the patterning devices 104. In an embodiment, the “inner” world may comprise climate containment and control facilities for substrate conditioning and/or liquid immersion (e.g. temperature and humidity control, immersion liquid flow, a gas knife, a gas shower, etc.). In an embodiment, frame 160 may be mechanically isolated from the substrate table 106 and its positioning device 116. Mechanical isolation may be provided, for example, by connecting the frame 160 to ground or a firm base separately from the frame for the substrate table 106 and/or its positioning device 116. In addition or alternatively, dampers may be provided between frame 160 and the structure to which it is connected, whether that structure is ground, a firm base or a frame supporting the substrate table 106 and/or its positioning device 116.

Frame 160 may be configured to be expandable and configurable to easily adopt any number of patterning devices 104. Additionally, each patterning device 104 may comprise a lens array 148 (see, e.g., FIGS. 4, 6 and 7). For example, in FIG. 3, there are depicted a number of patterning devices 104 that may further include the controller 140 and/or an associated lens array 148 arranged to be near or at the bottom of frame 160 just above the substrate. Accordingly, in an embodiment, a multi-column optical engine arrangement may be provided, with each optical engine comprising a patterning device 104 with optionally a lens array 148 and/or controller 140. In an embodiment, there is a free working distance between the substrate 114 and the lens array 148. This distance allows the substrate 114 and/or the lens array 148 to be moved to allow, for example, focus correction. In an embodiment, the free working distance is in the range of 1 to 250 microns, range of 5-150 microns, range of 10-75 microns or range of 20-50 microns.

Further, the lithographic apparatus 100 may comprise an alignment sensor 150. The alignment sensor may be used to facilitate determining of alignment between the patterning devices 104 and the substrate 114 before and/or during exposure of the substrate 114. The results of the alignment sensor 150 can be used by a controller of the lithographic apparatus 100 to control, for example, the positioning device 116 to position the substrate table 106 to improve alignment. For example, the alignment sensor 150 may measure one or more alignment marks on the substrate table 106 and then that measurement may be used in conjunction with an association between those one or more alignment marks and one or more alignment marks on the substrate 114 as measured in a measurement unit 200 to accurate position the substrate 114 relative to the patterning devices 104. In addition or alternatively, the controller may control, for example, a positioning device associated with the patterning devices 104 and/or lens array 148 to position the patterning device 104 or lens array 148 to improve alignment. In an embodiment, the alignment sensor 150 may include pattern recognition functionality/software to perform alignment.

The lithographic apparatus 100, in addition or alternatively, may comprise a level sensor 150. The level sensor 150 may be used to determine whether the substrate 114 and/or substrate table 106 is level with respect to the projection of the pattern from the patterning devices 104. The level sensor 150 can determine level before and/or during exposure of the substrate 114. The results of the level sensor 150 can be used by a controller of the lithographic apparatus 100 to control, for example, the positioning device 116 to position the substrate table 106 to improve leveling. In addition or alternatively, the controller may control, for example, a positioning device associated with a part of the projection system 108 (e.g., a lens array 148) to position an element of the projection system 108 (e.g., lens array 148 or a part of lens array 148) to improve leveling. In an embodiment, the level sensor may operate by projecting an ultrasonic beam at the substrate 114 and/or operate by projecting an electromagnetic beam of radiation at the substrate 114.

In an embodiment, results from the alignment sensor and/or the level sensor may be used to alter the pattern provided by the individually addressable elements 102. The pattern may be altered to correct, for example, distortion, which may arise from, e.g., optics (if any) between the individually addressable elements 102 and the substrate 114, irregularities in the positioning of the substrate 114, unevenness of the substrate 114, etc. Thus, results from the alignment sensor and/or the level sensor can be used to alter the projected pattern to effect a non-linear distortion correction. Non-linear distortion correction may be useful, for example, for flexible displays, which may not have consistent linear or non-linear distortion.

In operation of the lithographic apparatus 100, a substrate 114 is loaded onto the substrate table 106 using, for example, robot 210. The substrate 114 is then displaced in the Y-direction under the frame 160 and the patterning devices 104. The substrate 114 may be measured by level sensor and/or alignment sensor 150 and then is exposed to a pattern using patterning devices 104. For example, the substrate 114 is scanned through the focal plane (image plane) of the projection system 108, while the sub-beams, and hence the image spots, are switched at least partially ON or fully ON or OFF by the patterning devices 104. Features corresponding to the pattern of the patterning devices 104 are formed on the substrate 114. The individually addressable elements 102 may be operated, for example, to provide pixel-grid imaging as discussed herein.

In an embodiment, the substrate 114 may be scanned completely in the positive Y direction and then scanned completely in the negative Y direction. In such an embodiment, an additional level sensor and/or alignment sensor 150 on the opposite side of the patterning devices 104 may be required for the negative X direction scan.

FIG. 4 depicts a schematic side view of a programmable patterning device module of a lithographic apparatus according to an embodiment. As noted above, the patterning devices 104 may be provided to frame 160 by means of a module 152. While various FIG. 4 depicts various others components combined with a patterning device 104 in a module 152, this need not be the case.

In this embodiment, the patterning device 104 comprises a plurality of VECSELs or VCSELs, which are shown as a two-dimensional array thereof provided, for example, on a single substrate. In this embodiment, to save space, the plurality of VECSELs or VCSELs is arranged vertically, i.e., they emit in the X-direction. The plurality of VECSELs or VCSELs emits a plurality of beams. In an embodiment, the array may comprise 256 VECSELs or VCSELs, thus emitting 256 beams. Other number of VECSELs or VCSELs may be used.

Associated with patterning device 104 is beam reducer and delivery optics 154 which receives the radiation beams from the patterning device 104 and reduces the size of the beams. In this embodiment, the beam reducer and delivery optics 154 receives the beams projecting the X-direction and redirects them to travel in the Z-direction to a collimator/beam guide 156. The collimator/beam guide 156 collimates the beams and may perform other beam conditioning.

In this embodiment, a non-linear optic 158 to effect frequency multiplication (e.g., frequency doubling) receives the radiation beams from the collimator/beam guide 156. In an embodiment, the non-linear optic 158 comprises a KBBF prism coupling device 158. The KBBF prism coupling device 158 performs frequency multiplication of the radiation. In an embodiment, the non-linear optic 158 may comprise a different or additional suitable material for the frequency multiplication. As discussed above, there may be further frequency multiplication upstream of the non-linear optic 158, such as intra-cavity frequency doubling at the patterning device 104.

From the non-linear optic 158, the radiation beams are provided to a zone plate array 148. In an embodiment, each patterning device 104 may have an associated one zone plate array 148. Accordingly, there may be a plurality of separate zone plate arrays 148. In an embodiment, more than one patterning device 104 may share a zone plate array 148. The zone plate array 104 focuses the beams onto the substrate 116. Thus, in an embodiment, the module 152 may comprise all, or part, of the projection system 108. In an embodiment, an aperture structure having an aperture therein may be located between the VCSELs or VECSELs and the associated lenses of the zone plate array 148. The aperture structure can limit diffraction effects (e.g., prevent diffracted radiation from a radiation beam directed to a particular lens from impinging on another lens not associated with the radiation beam).

In an embodiment, each of the VCSELs or VECSELs 102 provides a beam to a lens of zone plate array 148. In an embodiment, each of the beams provided to the zone plate array 148 are sized and arranged to cover substantially the entirety of the cross-sectional width of the respective individual lenses of the zone plate array 148 during its movement. So, for example, in an embodiment, the cross-sectional widths of the beams provided to the zone plate array 148 are equal to or larger than the cross-sectional width of the individual lenses of the zone plate array 148 combined with the associated lens movement amplitude. For example, if the lens has a diameter of 100 microns and the movement amplitude in the X-direction is 20 microns, then the beam cross-sectional width would be about 120 microns or more. In an embodiment, the cross-sectional widths of the beams provided to the zone plate array 148 may be equal to (or perhaps slightly larger) than the cross-sectional width of the individual lenses of the zone plate array 148 and the beams are diverted to follow the respective lenses as they are moved in the X-direction. In an embodiment, the beam shape should have a “top-hat” profile, rather than, e.g., a Gaussian profile, when it reaches the lens and the spatial coherence should be good. Where part of the radiation falls outside of the lens cross-section, there should be, for example, an appropriate mask at the zone plate array 148 level (e.g., an opaque surface between the lenses of the zone plate array 148). In an embodiment, an appropriate beam guide may be provided to reduce or eliminate cross-talk between the beams. In an embodiment, to facilitate the mask and/or beam guide, the pitch between the lenses should be sufficiently large. In an embodiment, the lenses have a pitch of 160 microns. However, in an embodiment, the cross-sectional widths of the beams provided to the zone plate array 148 may be smaller than the cross-sectional width of the individual lenses of the zone plate array 148.

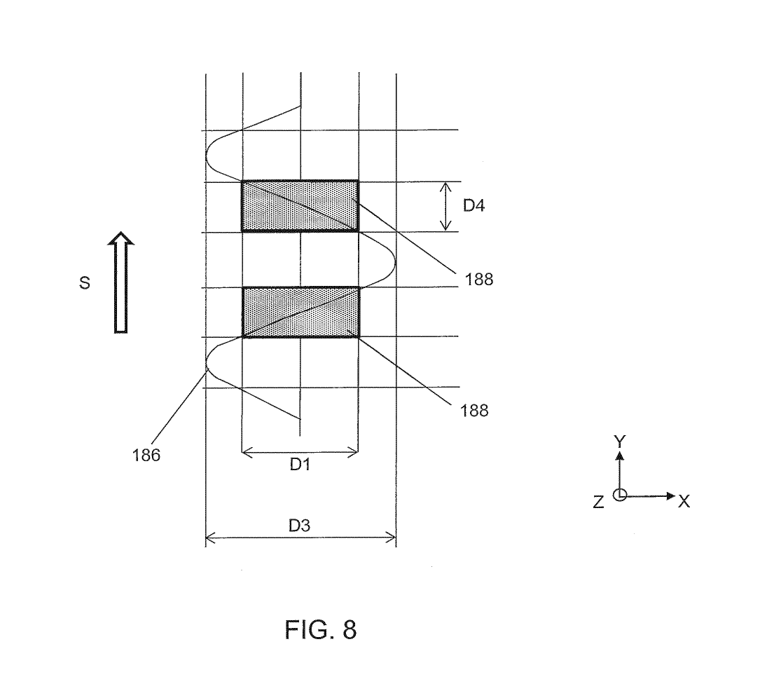

When a beam falls within the associated optically transmissive portion of a lens of zone plate array 148, the individually controllable element 102 (e.g., the VCSEL or VECSEL 102) can be switched “on” or “off” as appropriate to the desired pattern. The individually controllable element 102 (e.g., the VCSEL or VECSEL 102) may be switched “off” when the beam falls completely outside of the optically transmissive portion of the lens of the zone plate array 148. Thus, in an embodiment, the beam from an individually controllable element 102 passes through a single lens of zone plate array 148 at any one time. The resulting traversal of the lens by the beam from an individually controllable element 102 in combination with the displacement of the lens yields an associated imaged line or segment 188 (see FIG. 8) on the substrate from each individually controllable element 102 that is turned on.

In an embodiment, the zone plate array 148 may have similar thermal management control features as described with respect to the individually controllable elements 102. For example, the zone plate array 148 may have a cooling system. The zone plate array 148 may be made of, or attached to, a material of high thermal conductivity to facilitate conduction of heat from the array, where it may be removed or cooled.

In an embodiment, the zone plate array 148 and/or the individually controllable elements 102 are desirably kept at a substantially constant steady state temperature during exposure use. So, for example, all or many of the individually addressable elements 102 may be powered on, before exposure, to reach at or near a desired steady state temperature and optionally the radiation may be projected through the zone plate array 148 outside of the exposure area to “warm” up the zone plate array 148. During exposure, any one or more temperature control arrangements may be used to cool and/or heat the zone plate array 148 and/or the individually controllable elements 102 to maintain the steady state temperature. In an embodiment, any one or more temperature control arrangements may be used to heat the zone plate array 148 and/or the individually controllable elements 102 prior to exposure to reach at or near a desired steady state temperature. Then, during exposure, any one or more temperature control arrangements may be used to cool and/or heat the zone plate array 148 and/or the individually controllable elements 102 to maintain the steady state temperature. A measurement from a sensor can be used in a feedforward and/or feedback manner to maintain the steady state temperature. In an embodiment, each of a plurality of zone plate arrays 148 and/or arrays of individually controllable elements 102 may have the same steady state temperature or one or more of the plurality of zone plate arrays 148 and/or arrays of individually controllable elements 102 may have a different steady state temperature than one or more other of the plurality of zone plate arrays 148 and/or arrays of individually controllable elements 102. In an embodiment, a zone plate array 148 and/or the individually controllable elements 102 is heated to a temperature higher than the desired steady state temperature and then falls during exposure because of cooling applied by any one or more temperature control arrangements and/or because the usage of the individually addressable elements 102 isn't sufficient to maintain the temperature higher than the desired steady state temperature.

In an embodiment, a positioning device 162 controls the position of the zone plate array 148. The positioning device 162 may control the zone plate array 148 for leveling of the zone plate array 148 with the substrate or substrate table and/or for transmission image line sensor (TILS) alignment (as discussed hereafter).

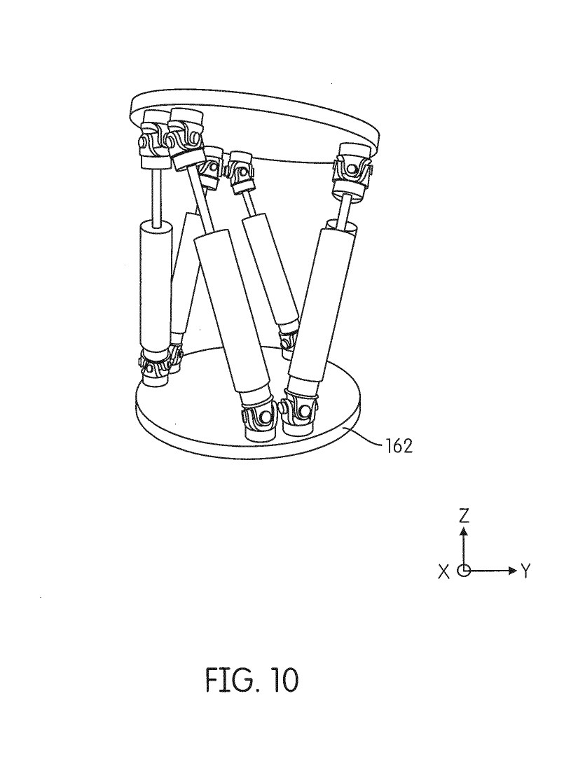

In an embodiment, the positioning device comprises a piezoactuator. In an embodiment, referring to FIG. 10, the positioning device comprises a Gough Stewart positioning unit. In an embodiment, the positioning device 162 can control the zone plate array 148 in at least 1 degree of freedom, in at least 3 degrees of freedom, or in 6 degrees of freedom. In an embodiment, the positioning device 162 comprises a miniaturized piezo Gough/Stewart six degree of freedom actuator. Each zone plate array 148 may be controlled by its own positioning device 162. In an embodiment, to calculate the control signals for the positioning device 162, a controller 164 may be provided to drive the positioning device 162. Control information is provided from the controller 164 via the bus 142 to other controllers and similarly control information (e.g., position correction information) is provided from one or more external controllers and/or sensor via the bus 142 to the controller 164. In an embodiment, the controller 164 may be associated with a single positioning device 162 or may be shared with a plurality of positioning devices 162. In an embodiment, a position sensor may be provided to determine the position of a zone plate array 148 in up to 6 degrees of freedom. For example, the zone plate array position sensor may comprise an interferometer. In an embodiment, the zone plate array position sensor may comprise an encoder which may be used to detect one or more single dimension encoder gratings and/or one or more two dimensional encoder gratings.

Referring to FIG. 5, a schematic bottom view of an arrangement of a plurality of modules 152 of FIG. 4 is depicted. These modules would be arranged on a length of the frame 160 in the X-direction. The zone plate array 148 of each module 152 would be exposed at the bottom of frame just above the substrate/substrate table. In an embodiment, the combined length L of the zone plate arrays 148 may be the cross-section dimension (e.g., diameter) of the substrate 114 (e.g., 300 mm). The combined zone plate arrays 148 may be termed an exposure head. FIG. 4 depicts that the exposure head comprises two opposing exposure bank rows of zone plate arrays 148—a near exposure bank row 166 (e.g., it exposes the substrate first) and a far exposure bank row 168. In an embodiment, as shown in FIG. 5, the zone plate arrays 148 in the near exposure bank row 166 may be staggered/interleaved in the X-direction with respect to the zone plate arrays 148 in the far exposure bank row 168. This can allow for gaps between exposure areas of the zone plate array of the near exposure bank row 166 to be filled by the exposure areas of far exposure bank row 168. Accordingly, since the exposure areas should be stitched within the critical dimension uniformity (CDU) criteria of, for example, less than or equal to 2 nanometers, less than or equal to 5 nanometers, less than or equal to 10 nanometers or less than or equal to 50 nanometers, the zone plate arrays 148 should be properly aligned.

In FIG. 5, fifty nine (59) zone plate arrays 148 are depicted each zone plate array itself covering 5120 microns in length. A different number of zone plate arrays may be provided each of a different length. As shown, the zone plate arrays 148 are interleaved to cover the whole cross-sectional dimension (e.g., diameter) of a substrate. More zone plate arrays 148 may be added if a wider substrate is used and less zone plate arrays 148 for a narrower substrate. Thus, the apparatus may flexibly adapt to different substrate sizes. An advantage of the exposure area extending across the substrate is that a consistent productivity may be achieved under varying conditions while still maintaining a moderate image data bandwidth requirement. Further, the exposure area extending across the substrate enables reduction in macroscopic mechanical movement by having a relatively slow linear scanning movement. Thus, large mechanical movements may be avoided. The relatively slow motion may enable tight stitching CDU requirements to be met despite uncorrectable stochastic variables.

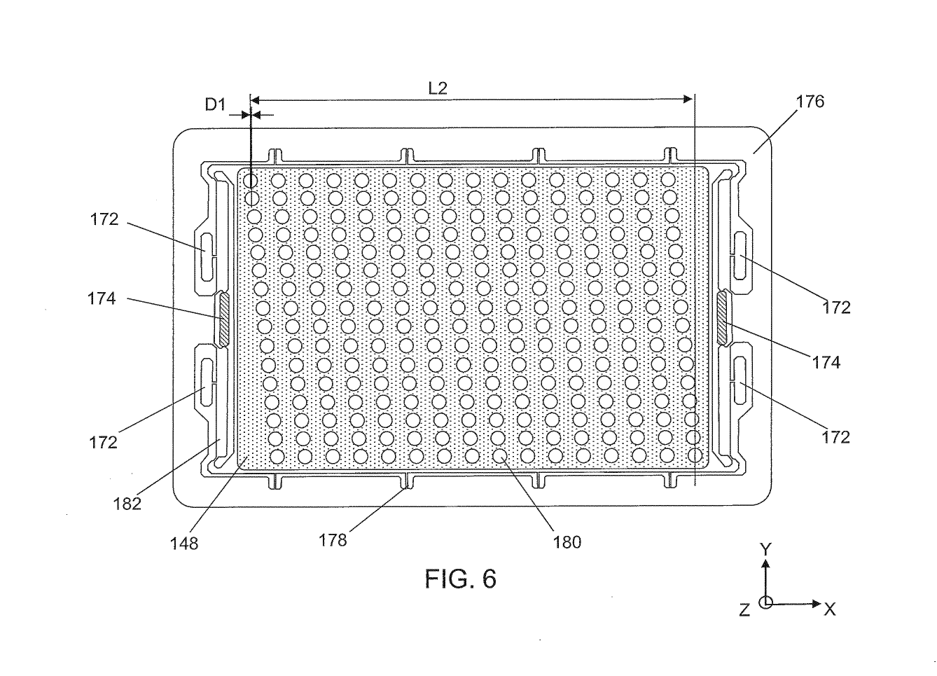

FIG. 6 depicts a schematic top view of a lens array arrangement of a lithographic apparatus according to an embodiment. The lens array arrangement includes a zone plate array 148 comprising a plurality of lenses 180. In this embodiment, there are 256 lenses. In an embodiment, each of the lenses may have a diameter of about 100 microns. The 256 lenses may cover a scan line length L2 of 5120 microns. In the embodiment depicted in FIG. 6, the lenses are arranged in horizontally offset diagonal lines of lenses in a 16×16 lens sawtooth configuration. In an embodiment, the lenses are horizontally from each other at, for example, a 20 micron distance D1. In an embodiment, the lines may be arranged vertically, rather than diagonally, if the substrate scans at angle to the lines, i.e., the scan motion is not parallel to the vertical direction of the lines.

In an embodiment, the array 148 is supported in, or by, a frame 176 of the lens array arrangement. In an embodiment, the frame 176 comprises metal. In an embodiment, the array 148 is connected to the frame 176 by one or more mount points 172. In an embodiment, the array 148 may be connected to a frame 182, which in turn is connected to the frame 176 by the one or more mount points 172. In an embodiment, the frame 176 and the mount point 172 may be one monolithic structure. In an embodiment, the frame 176, the mount point 172 and the frame 182 may be one monolithic structure. The frame 176 and/or frame 182 may be constructed from a metal sheet, which may have the same thickness as the zone array plate 148; this thickness matching may allow for a correct center of gravity along the Z axis and allow for correct proximity of the array 148 to the substrate surface. In an embodiment, there may be one or more flexible mounts 178 to laterally support the zone array plate 148.

In an embodiment, the lens array arrangement comprises one or more actuators 174 to displace the zone plate array 148. In an embodiment, the actuator 174 comprises a piezoactuator. In an embodiment, the actuator 174 accelerates the zone plate array 148 (including the frame 182, if provided) relative to the frame 176. The frame 176 may work as a balance mass to absorb the vibration. In FIG. 6, two actuators 174 are depicted.

In an embodiment, the zone plate array 148 (and optionally the frame 182) is connected to the frame 176 via spring hinges as the mounts 172. The spring hinges may be tuned to an eigenfrequency of the assembly of, for example, 25 KHz. The connection point of a hinge is located substantially at the center of rotation of a lever arm connected to the actuator 174. This helps to isolate the oscillation.

In an embodiment, the actuation of the actuator 174 may cause oscillation of the zone plate array 148 in substantially the X-direction. Thus, the zone plate array 148 may oscillate with a close to sine like motion in the X direction at an eigenfrequency of, for example, 25 KHz. This oscillation may have an amplitude of, for example, 34 microns. This oscillation will cause the beam to scan in the X-direction by virtue of the lenses of the zone plate array 148. Further, as will discussed further below, the actuation of the actuator 174 may cause oscillation of the zone plate array 148 in substantially the Y-direction in addition to, or alternatively to, oscillation in the X-direction.

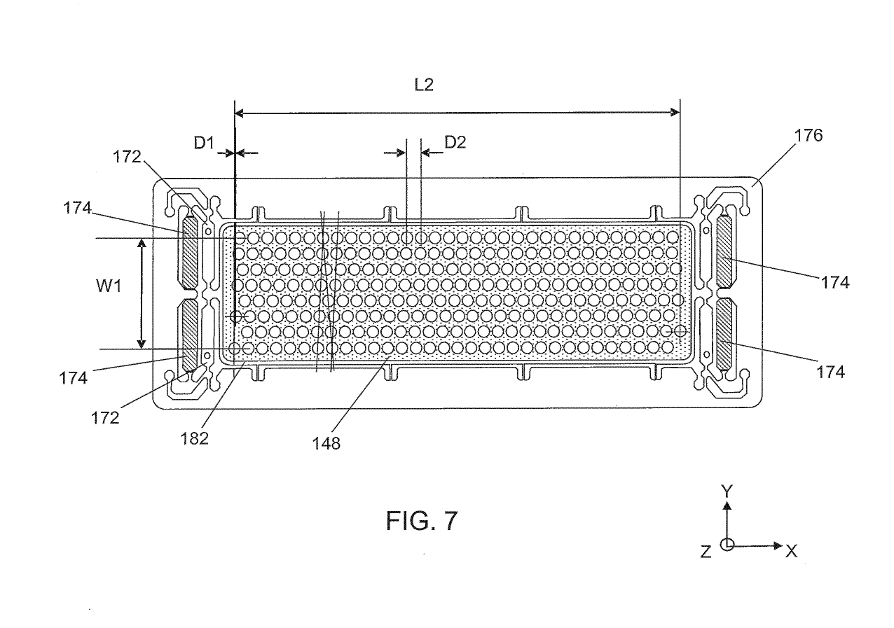

FIG. 7 depicts a schematic top view of a lens array arrangement of a lithographic apparatus according to an embodiment. The lens arrangement of FIG. 7 is similar to the lens array arrangement of FIG. 6. In this embodiment, the lenses are arranged in a different configuration. Rather than a 16×16 array, the lenses are arranged in a 8×32 configuration. Further, rather than a sawtooth pattern, the lenses are in arranged in a triangle pattern as schematically shown by the lines connecting lenses diagonally in FIG. 7. In an embodiment, the lenses are horizontally from each other at, for example, a 20 micron distance D1. In an embodiment, horizontally adjacent lenses are spaced from each other at, for example, a 160 micron gap D2. In an embodiment, the lenses may have a width W1 of 1120 microns.

This lens layout may provide one or more improvements. For example, this design may reduce the FIFO memory capacity of the controller 140 in half. The triangular scan pattern may remove a potential stitching error between lenses in a top horizontal line and a bottom horizontal line by half. This layout may provide better overlay control due to its smaller surface. This layout may reduce the mass of the zone plate array 148 by half. This layout may reduce the size of the non-linear optic 158 in the beam path.

Further, as shown in FIG. 7, a different arrangement of one or more actuators 174, frame 176 and frame 182 is provided. For example, in this embodiment, there are four (4) actuators 174.

Referring to FIG. 8, a schematic illustration of the radiation projection of a lithographic apparatus according to an embodiment is depicted. The relative scanning motion between the substrate and the zone plate array 148 is shown by arrow S in the Y-direction. Further, as discussed above, the actuator 174 causes an oscillation, e.g., sine-like, of the zone plate array 148 in the X-direction. In an embodiment, the oscillation may have an amplitude D3 of, for example, 34 microns. In FIG. 8, the oscillation in combination with the relative scanning is shown by the curve 186. So, with an oscillation frequency of 25 KHz, there is a 40 microsecond period. As shown in FIG. 8, the actual exposure movements have a duty cycle of 50%, i.e., there are 2 exposure periods per cycle. So, as a result, there are 50,000 segments/scan lines 188 of width D1 (in this case, 20 microns) per second per beam/lens. Thus, every segment/scan line 188 takes 10 microseconds. With a relative scanning motion S of 1 mm/s, each segment/scan line corresponds to 10 nm displacement D4 in the Y-direction. So for an array of 256 lenses covering a scan line length of 5120 microns, there are about 1000 spots per period, which is about a 100 M samples that translates to 50 MHz wave generation.

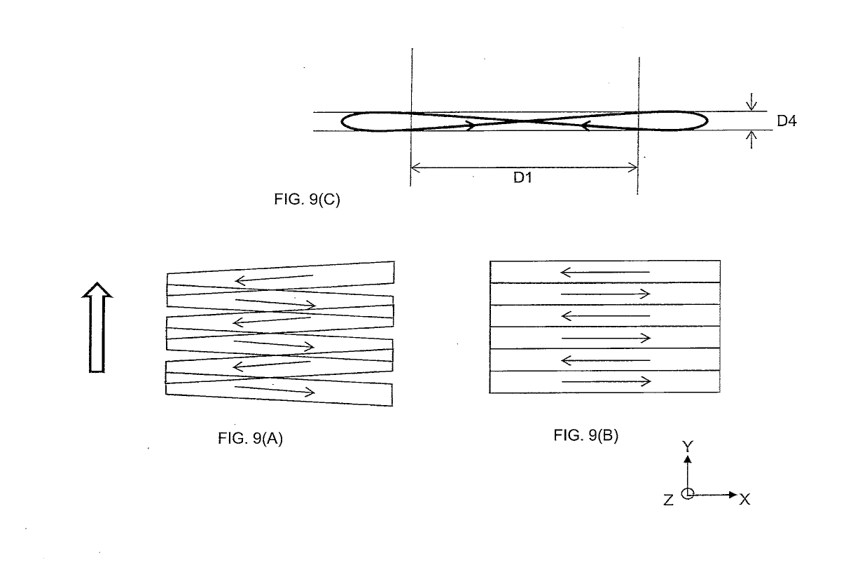

As can be seen in FIG. 8, an exposure beam will tend to follow a diagonal path through the segment/scan line 188 due to the relative scanning motion S of, for example, 1 mm/s. Thus, FIG. 9(A) generally depicts the exposure beam movement. So, to compensate for the scanning motion (and to have an exposure movement as generally depicted in FIG. 9(B)), a modulation in the Y-direction of double the frequency of the X-direction oscillation (e.g., 50 KHz where the X-direction oscillation is 25 KHz) is added with an amplitude substantially equal to the displacement D4 of the segment/scan line 188 (e.g., 10 nm). Thus, the zone plate array 148 will describe a generally Lissajous like path. This helps assure that the segments/scan lines are exposed substantially parallel to each other. Some active additional modulation in both the X and Y directions should be provided to help assure substantially constant speed and linear movement during the various exposure phases. In an embodiment, the actuator 174 drives the zone plate array 148, controls the synchronization and provides precise control over the Lissajous-like exposure movement.

To help effect the precise positioning of the radiation beams on the substrate, the apparatus may comprise a sensor 145 to measure one or more parameters associated with the radiation beams projected onto the substrate. Referring to FIG. 3, example locations of the sensor 145 are depicted. In an embodiment, one or more sensors 145 are provided in or on the substrate table 106 to hold substrate 114. For example, a sensor 145 may be provided at the leading side of the substrate table 106 (as shown) and/or the trailing side of the substrate table 106 (as shown). Desirably, they are located at position that would not be covered by the substrate 116. In an alternative or additional example, a sensor may be provided at a side edge of the substrate table 106 (not shown), desirably at a location that would not be covered by the substrate 116. The sensor 145 at the leading side of the substrate table 106 can be used for pre-exposure detection. The sensor 145 at the trailing side of the substrate table 106 can be used for post-exposure detection. A sensor 145 at the side edge of the substrate table 106 can be used for detection during exposure (“on-the-fly” detection). In an embodiment, sensor 145 may be on the frame 160 (e.g., as or part of sensor 150) to receive radiation from the zone plate array 148 via a beam redirecting structure (e.g., a reflective mirror arrangement arranged at the location of sensor 145 on the substrate table 106 as shown in FIG. 3) or to receive radiation in the beam path from the VECSELs or VCSELs to the zone plate array 148 (e.g., a beam splitter). This embodiment may allow “on-the-fly” sensing in addition to or alternatively to pre- and/or post-exposure sensing. Additionally or alternatively, sensor 145, or a beam redirecting structure to a sensor 145, may be provide on a sensor structure separate from the substrate table 106 and moveable with respect to the frame 160. The structure may be movable by means of an actuator. In an embodiment, the sensor structure is located under the path of where the substrate table 106 would move or at the side of the path. In an embodiment, the structure may be moved by an actuator to the position where the sensor 145 of substrate table 106 is shown in FIG. 3 if the substrate table 106 were not there, such movement may be, for example, in the Z-direction or in the X- and/or Y-direction if the structure were at the side of the path. In an embodiment, the sensor structure is located above the path of where the substrate table would move. In an embodiment, the sensor structure may be moved by an actuator (e.g., rotated) to under the zone plate array 148. In an embodiment, the sensor structure may be attached to frame 160 and displaceable with respect to frame 160 (e.g., rotated).

In operation to measure a characteristic of the radiation that is or to be transmitted toward the substrate, the sensor 145 (or the beam redirecting structure) is located in a path of radiation from a zone plate array 148 by, for example, moving the sensor 145. So, as an example, referring to FIG. 3, the substrate table 106 may be moved to position sensor 145 (or beam redirecting structure) in a path of radiation from a zone plate array 148. In that case, the sensor 145 (or beam redirecting structure) is positioned into a radiation beam from the zone plate array 148 at the exposure region 204. Once the sensor 145 (or the beam redirecting structure) is located in the path of radiation, the sensor 145 can detect the radiation and measure one or more parameters in respect of the radiation. To facilitate sensing, the sensor 145 (or beam redirecting structure) may move with respect to the zone plate array 148 and/or the zone plate array 148 may be moved with respect to the sensor 145 (or beam redirecting structure).

In an embodiment, the sensor 145 may facilitate alignment of the beams onto the desired locations on the substrate. Thus, in an embodiment, to provide proper and accurate exposure beam alignment, a transmission image line sensor 145 is used to receive one or more of the radiation beams for measurement. In an embodiment, the sensor 145 extends across the full substrate width.

The sensor 145 may be used to calibrate one or more of the radiation beams. For example, the location of the spot of a radiation beam can be detected by the sensor 145 prior to exposure and the system accordingly calibrated. The exposure can then be regulated based on this expected location of the spot (e.g., the position of the substrate 114 is controlled, the position of the beam is controlled (e.g., through movement of the zone plate array 148 or a lens thereof), the turning “OFF” or “ON” of a VECSEL or VCSEL is controlled, etc.). Further, calibrations may take place subsequently. For example, a calibration may take place immediately after exposure before a further exposure using, for example, a sensor 145 on the trailing side of the substrate table 106. Calibration may take place before each exposure, after a certain number of exposures, etc. Further, the location of the spot of a radiation beam may be detected “on-the-fly” using a sensor 145 at, e.g., the side of the substrate 114 and the exposure is accordingly regulated. There may be recalibration based on the “on-the-fly” sensing.

In an embodiment operation of the sensor 145, before exposure of the substrate is commenced, beams from the zone plate arrays 148 on frame 160 are received and measured by the sensor 145 at the leading side of the substrate table 106 (i.e., the sensor 145 nearest the frame 160 as shown in FIG. 3). For example, the locations (in the X-Y plane) of the spots of radiation from the radiation beams are measured. In an embodiment, the sensor 145 may additionally or alternatively determine the rotation about the X, Y and/or Z axes and/or the location in the Z-direction (as relatedly discussed below). The relative alignment of the beams is analyzed.

In an embodiment and if needed, the positions of one or more of the zone plate arrays 148 on the frame 160 are re-aligned such that the radiation beams are properly aligned with respect to each other. In an embodiment, the realignment may be performed by positioning device 162. In an embodiment, the re-alignment may occur in 1 degree of freedom, 2 degrees of freedom, at least 3 degrees of freedom or in 6 degrees of freedom. In an embodiment, individual lenses may be re-aligned as discussed hereafter.

After exposure of the substrate, the sensor 145 at the trailing side of the substrate table 106 (i.e., the sensor 145 furthest from the frame 160 as shown in FIG. 3) re-validates the projection of the radiation beams. If, for example, the results still match and the dynamic performance of the substrate table 106 during the exposure of the substrate 114 checks out, the exposure of the substrate 114 may be considered satisfactory. Thus, the radiation beams are calibrated initially using the leading side sensor 145 and the positioning accuracy is validated again at the end of the exposure of the substrate using the trailing side sensor 145.

Additionally or alternatively, one or more characteristics of the radiation that is, or to be, transmitted toward the substrate are measured by sensor 145. In an embodiment, exposure intensity of the radiation beams (and thus the VECSELs or VCSELs) may be validated and/or calibrated. Additionally or alternatively, uniformity of radiation of radiation beam and/or a cross-sectional size or area of the spot of the beam of radiation.

In an embodiment, sensor 145 may be configured to measure focus for each radiation beam from the zone plate array(s) 148 or for a plurality of radiation beams from the zone plate array(s) 148. If an out of focus condition is detected, the focus may be corrected for each lens of zone plate array 148 or for a plurality of lenses of the zone plate array 148. Focus may be corrected by, for example, moving an array 148 in a Z-direction (and/or about the X-axis and/or about the Y-axis).

In an embodiment, focus, aberration, etc. of a lens of the zone plate array 148 may be corrected using localized heating at or near the particular lens using a heat absorbing spot or area at the top and/or bottom of the array 148 which can be heated using one or more beams of radiation (e.g., one or more infrared beams). In an embodiment, the one or more heating beams are interleaved with the exposure beams. The one or more heating beams may be supplied by, e.g., a VECSEL or VCSEL array. The one or more heating beams may be coupled in the beam path with an appropriate beam splitter or directly via an angled path. Such an implementation combined with a bias heating control could potentially allow for control of lens spacing and/or lens array curvature at a precise level.

Additionally or alternatively, the zone plate array 148 may comprise an appropriate piezoelectric material (e.g., crystalline quartz) in which localized movement can be induced by localized piezoelectric effect. Thus, one or more electric conductors may run in or on the zone plate array 148 and may apply electrical charge at the appropriate location to cause movement in the piezoelectric material of the zone plate array 148, which movement causes localized movement of one or more lenses of the zone plate array 148.

Further, in an embodiment, the timing of exposure may be varied to stretch or compress the fragments 188 of a zone plate array 148 in the X-direction for certain corrections.

And, at the given precision, the sensor 145 itself may not be perfect to the nanometer level. Thus, the sensor 145 may need to be mapped to define its imperfection(s), if any.

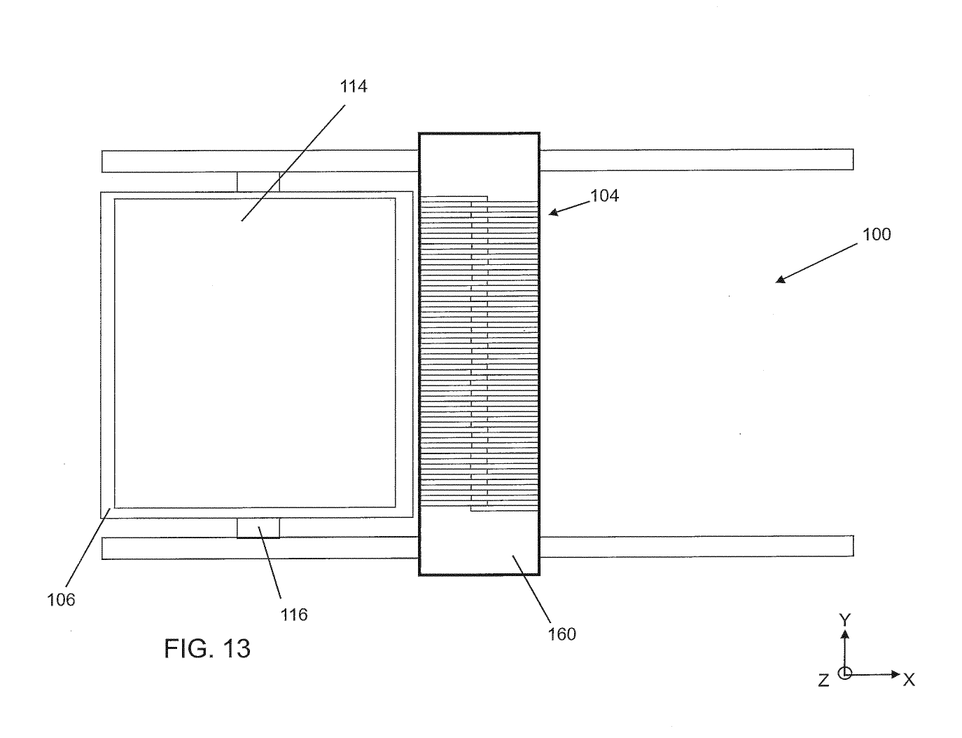

FIG. 13 shows schematically how an entire substrate 114 may be exposed in a single scan, by using a plurality of optical engines, each optical engine comprising one or more individually addressable elements. Each optical engine may comprise a separate patterning device 104 and optionally a separate projection system 108 and/or radiation system as described above. It is to be appreciated, however, that two or more optical engines may share at least a part of one or more of the radiation system, patterning device 104, and/or projection system 108. In an embodiment, each optical engine comprises a patterning device 104 and a zone plate array 148. In this embodiment, eight optical engines are depicted schematically as covering the width of the substrate 114 for clarity. As can be seen in FIG. 5, there may be many more in practice. Eight arrays of radiation spots (not shown) are produced by the eight optical engines, arranged in two rows 166, 168 in a ‘chess board’ or staggered configuration such that the edge of one array of radiation spots slightly overlaps with the edge of the adjacent array of radiation spots. In an embodiment, the optical engines may be arranged in more rows. In this way, a band of radiation extends across the width of the substrate W, allowing exposure of the entire substrate to be performed in a single scan. Such “full width” single pass exposure helps to avoid possible stitching issues of connecting two or more passes and may also reduce machine footprint as the substrate may not need to be moved in a direction transverse to the substrate pass direction. It will be appreciated that any suitable number of optical engines may be used. In an embodiment, the number of optical engines is at least 2, at least 4, at least 8, at least 10, at least 20, at least 30, or at least 50. In an embodiment, the number of optical engines is less than 1000, e.g. less than 500, less than 250, less than 100 or less than 75.

In the embodiments described herein, a controller is provided to control the individually addressable elements (e.g., the VECSELs or VCSELs). For example, in an example where the individually addressable elements are radiation emitting devices, the controller may control when the individually addressable elements are turned ON or OFF and enable high frequency modulation of the individually addressable elements. The controller may control the power of the radiation emitted by one or more of the individually addressable elements. The controller may modulate the intensity of radiation emitted by one or more of the individually addressable elements. The controller may control/adjust intensity uniformity across all or part of an array of individually addressable elements. The controller may adjust the radiation output of the individually addressable elements to correct for imaging errors, e.g., etendue and optical aberrations (e.g., coma, astigmatism, etc.)

In lithography, a desired feature may be created on a substrate by selectively exposing a layer of resist on a substrate to radiation, e.g. by exposing the layer of resist to patterned radiation. Areas of the resist receiving a certain minimum radiation dose (“dose threshold”) undergo a chemical reaction, whereas other areas remain unchanged. The thus created chemical differences in the resist layer allow for developing the resist, i.e. selectively removing either the areas having received at least the minimum dose or removing the areas that did not receive the minimum dose. As a result, part of the substrate is still protected by a resist whereas the areas of the substrate from which resist is removed are exposed, allowing e.g. for additional processing steps, for instance selective etching of the substrate, selective metal deposition, etc. thereby creating the desired feature. Patterning the radiation may be effected by setting the individually controllable elements in a patterning device such that the radiation that is transmitted to an area of the resist layer on the substrate within the desired feature is at a sufficiently high intensity that the area receives a dose of radiation above the dose threshold during the exposure, whereas other areas on the substrate receive a radiation dose below the dose threshold by setting the corresponding individually controllable elements to provide a zero or significantly lower radiation intensity.

In practice, the radiation dose at the edges of the desired feature may not abruptly change from a given maximum dose to zero dose even if the individually controllable elements are set to provide the maximum radiation intensity on one side of the feature boundary and the minimum radiation intensity on the other side. Instead, due to diffractive effects, the level of the radiation dose may drop off across a transition zone. The position of the boundary of the desired feature ultimately formed after developing the resist is then determined by the position at which the received dose drops below the radiation dose threshold. The profile of the drop-off of radiation dose across the transition zone, and hence the precise position of the feature boundary, can be controlled more precisely by setting the individually controllable elements that provide radiation to points on the substrate that are on or near the feature boundary not only to maximum or minimum intensity levels but also to intensity levels between the maximum and minimum intensity levels. This is commonly referred to as “grayscaling” or “grayleveling”.

Grayscaling may provide greater control of the position of the feature boundaries than is possible in a lithography system in which the radiation intensity provided to the substrate by a given individually controllable element can only be set to two values (namely just a maximum value and a minimum value). In an embodiment, at least three different radiation intensity values can be projected onto the substrate, e.g. at least 4 radiation intensity values, at least 8 radiation intensity values, at least 16 radiation intensity values, at least 32 radiation intensity values, at least 64 radiation intensity values, at least 100 radiation intensity values, at least 128 radiation intensity values, or at least 256 radiation intensity values, at least 512 radiation intensity values, at least 1024 intensity values or at least 2048 intensity values. If the patterning device is a radiation source itself (e.g. an array of VECSELs or VCSELs), grayscaling may be effected, e.g., by controlling the intensity levels of the radiation being transmitted. If the contrast device is a micromirror device, grayscaling may be effected, e.g., by controlling the tilting angles of the micromirrors. Also, grayscaling may be effected by grouping a plurality of programmable elements in the contrast device and controlling the number of elements within the group that are switched on or off at a given time.

In one example, the patterning device may have a series of states including: (a) a black state in which radiation provided is a minimum, or even a zero contribution to the intensity distribution of its corresponding pixel; (b) a whitest state in which the radiation provided makes a maximum contribution; and (c) a plurality of states in between in which the radiation provided makes intermediate contributions. The states are divided into a normal set, used for normal beam patterning/printing, and a compensation set, used for compensating for the effects of defective elements. The normal set comprises the black state and a first group of the intermediate states. This first group will be described as gray states, and they are selectable to provide progressively increasing contributions to corresponding pixel intensity from the minimum black value up to a certain normal maximum. The compensation set comprises the remaining, second group of intermediate states together with the whitest state. This second group of intermediate states will be described as white states, and they are selectable to provide contributions greater than the normal maximum, progressively increasing up to the true maximum corresponding to the whitest state. Although the second group of intermediate states is described as white states, it will be appreciated that this is simply to facilitate the distinction between the normal and compensatory exposure steps. The entire plurality of states could alternatively be described as a sequence of gray states, between black and white, selectable to enable grayscale printing.

It should be appreciated that grayscaling may be used for additional or alternative purposes to that described above. For example, the processing of the substrate after the exposure may be tuned such that there are more than two potential responses of regions of the substrate, dependent on received radiation dose level. For example, a portion of the substrate receiving a radiation dose below a first threshold responds in a first manner; a portion of the substrate receiving a radiation dose above the first threshold but below a second threshold responds in a second manner; and a portion of the substrate receiving a radiation dose above the second threshold responds in a third manner. Accordingly, grayscaling may be used to provide a radiation dose profile across the substrate having more than two desired dose levels. In an embodiment, the radiation dose profile has at least 2 desired dose levels, e.g. at least 3 desired radiation dose levels, at least 4 desired radiation dose levels, at least 6 desired radiation dose levels or at least 8 desired radiation dose levels.

It should further be appreciated that the radiation dose profile may be controlled by methods other than by merely controlling the intensity of the radiation received at each point on the substrate, as described above. For example, the radiation dose received by each point on the substrate may alternatively or additionally be controlled by controlling the duration of the exposure of said point. As a further example, each point on the substrate may potentially receive radiation in a plurality of successive exposures. The radiation dose received by each point may, therefore, be alternatively or additionally controlled by exposing said point using a selected subset of said plurality of successive exposures.

In order to form the pattern on the substrate, each of the individually controllable elements in the patterning device is set to the requisite state at each applicable stage during the exposure process. Therefore control signals, representing the requisite states, are transmitted to each of the individually controllable elements. Desirably, the lithographic apparatus includes a control system 300 that generates the control signals. The pattern to be formed on the substrate may be provided to the lithographic apparatus from, e.g., a fab image host network 302 in, e.g., a vector-defined format e.g., GDSII. In an embodiment, the pattern data may be in an orthogonal square pixel format that allows for, e.g., a standard lossless bitmap file format.

To convert the design information into the control signals for each individually controllable element, the control system 300 includes one or more data manipulation devices, each configured to perform a processing step on a data stream that represents the pattern. The data manipulation devices may collectively be referred to as the “datapath”. The data manipulation devices of the datapath may be configured to perform one or more of the following functions: converting vector-based design information into bitmap pattern data; converting bitmap pattern data into a required radiation dose map (namely a required radiation dose profile across the substrate); converting a required radiation dose map into required radiation intensity values for each individually controllable element; and converting the required radiation intensity values for each individually controllable element into corresponding control signals.

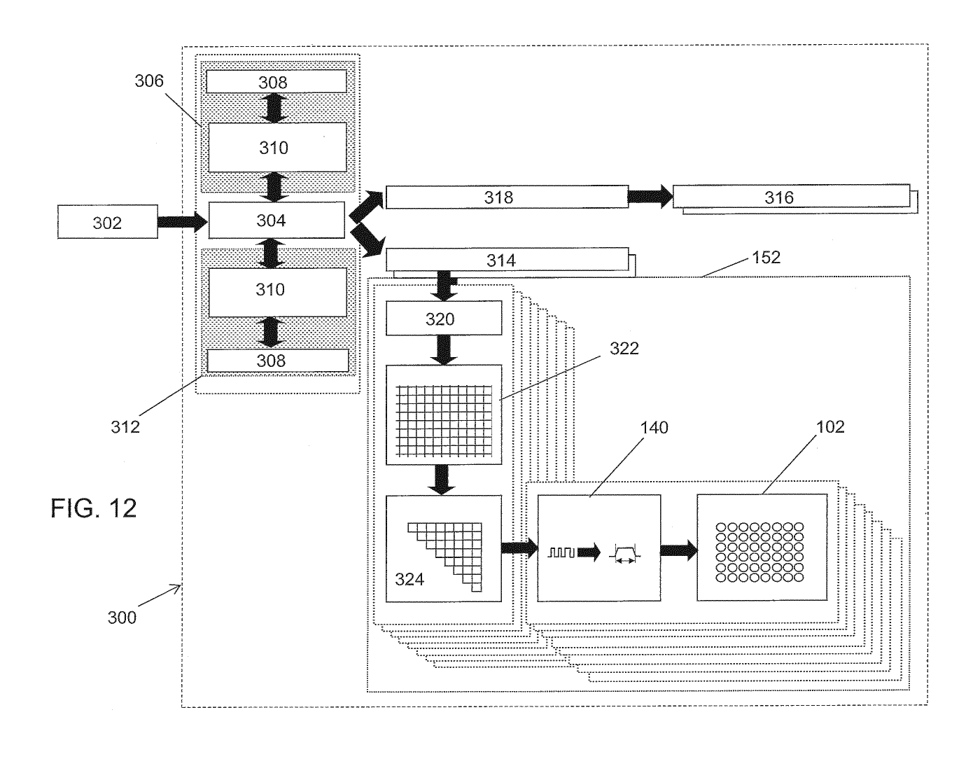

FIG. 12 depicts a schematic of the image data path of a lithographic apparatus according to an embodiment. In this embodiment, the system controls 256 individually controllable elements (e.g., VCSELs or VECSELs). Of course, the image data path may be set up for a different number of individually controllable elements. Further, while specific numbers, type, etc. of lines, memories, controllers, etc. are discussed herein in respect of the image data path, the invention is not necessarily so limited and an embodiment of the invention may comprise a different number, type, etc. of lines and/or memories, and/or controllers, etc.

Referring to FIG. 12, an example control system 300 receives a pattern (image) to be projected on the substrate from, e.g., a fab image host network 302, at an optical transceiver and switch 304. In an embodiment, the path to, and from, the optical transceiver and switch 304 is fiber optic line. In an embodiment, the fiber optic line comprises four (4) 32 fiber (640 Gbps bandwidth).

From the optical transceiver and switch 304, the pattern is stored in memory. In an embodiment, the memory comprises one or more solid-state drives (SSDs). In an embodiment, the pattern is stored as into at two different data stores. One data store is in use during exposure and the other is available as backup and/or open for additional image upload from the image host. Thus, in an embodiment, there is alternating use of the store 306, 312. Accordingly, in an embodiment, there is a first pattern data store 306 comprising a memory (e.g., a solid-state driver) 308 and associated controller 310 to transfer data between the memory 308 and the optical transceiver and switch 304. The second pattern data store 312 may similarly comprise a memory 308 and associated controller 310. In an embodiment, the specifications for the second pattern data store 312 are the same as the first pattern data store 306. In an embodiment, each data store 306, 312 is a buffer of a size of 24 full field pattern images.

In an embodiment, the memory comprises two hundred and fifty six (256) 256 GB solid-state drives (64 Tb) that, in an embodiment, do not have their housing to facilitate cooling. In an embodiment, the memory may comprise a plurality of PCI-Express solid-state drives (optionally of M.2 class format) which allow a sustained bandwidth of 1.4 GByte per second; this arrangement may eliminate having data streams of two conventional solid-state drives per optical link in favor of a single such solid-state drive per optical link. In an embodiment, each SSD is equipped with a SATA 600 interface and a rated read speed of at least 500 MB/second. In view of the large number of SSD cards involved, robustness is desirable. Accordingly, in an embodiment, the data store 306, 312 is a machine adapted combined version of what conceptually is similar to RAID 0 and RAID 1. Both individual data stores 306, 312 are backing each other up in a RAID 1 fashion (i.e. the image data for a specific image is present in both stores 306, 312) while within each data store all the SSDs are accessed simultaneous like RAID 0 to generate the image data stream with the bandwidth of 80 GB/second on the internal optical bus. In case of, for example, a SSD failure, the data store 306 can be exchanged immediately electronically with the data store 312 (or vice versa) and processing can continue. This might interrupt an image data transfer that might be in process at that time but that can be recovered afterwards. Since current SSDs comprise NAND flash memory, they may have a limited number of write cycles. Thus, in an embodiment, the controller 310, 312 may prevent a large number of writes in the same area by a randomizer mechanism. Further, in an embodiment, the capacity of the SSDs is made four times larger than is necessary. This helps reduce the write intensities. For example, in general, one would expect a data store to read an image many times more than writing it. So, enlarging the capacity may reduce the wear quadratically.

In an embodiment, the controller 310 comprises an array controller comprising four (4) disk controllers for each 64 solid-state drives with four (4) 32 optical out fiber. Each controller takes care of data storage/retrieval and synchronization of the data transfer in parallel for its SSD cards in parallel and the 3 neighboring controllers within that same data store. Per controller the data output is consolidated in a 2 to 1 TDM fashion on a 32 fiber optical cable via the optical transceiver and switch 304 to the optical multi-drop bus controller or the optical fab image host network interface 302.

From the optical transceiver and switch 304, the image data is provided toward optical multi-drop bus controllers 314, 316 for the exposure bank rows 166, 168. The optical multi-drop bus controller 314 provides the image data to the near exposure bank row 166. The optical multi-drop bus controller 316 provides the image data to the far exposure bank row 168. In an embodiment, each optical multi-drop bus controller 314, 316 comprises two (2) 16 optical multi-drop bus controllers. Since there is a time lag between the data required for the exposure bank rows and given that the image data is presented on the optical bus only once per image row, a delay line 318 is introduced that, in, e.g., a FIFO form, pushes the data to the optical bus for the far exposure bank row 168. In an embodiment, delay line 318 comprises ˜160 GB DRAM−(2 sec.).

From the optical multi-drop bus controllers 314, 316, the pattern data is provided to a control system for each patterning device 104. In an embodiment, the control system for each patterning device 104 comprises an optical receiver and fast capture buffer 320, a matrix switch 322 and a FiFo storage 324. From the FiFo storage 324, the data is provided to a wave (impulse) generator 140 to control the radiation output of the individually controllable elements 102 (e.g., VCSELs or VECSELs). In an embodiment, the various components may be connected by two-hundred and fifty (256) 500 Mbps (128 Gbps bandwidth) lines. In an embodiment, the optical receiver and fast capture buffer 320, the matrix switch 322, the FiFo storage 324, the wave (impulse) generator 140 and the individually controllable elements 102 are included in module 152 (although they do not need to be). In an embodiment, just the wave (impulse) generator 140 and the individually controllable elements 102 are included in module 152.

In an embodiment, the output signal from the wave generators 140 are driven as an impulse length modulated signal rather than an amplified analog signal. This may allow efficient, consistent non-linear optic conversion because non-linear optic conversion efficiency is driven by beam intensity.

As will be appreciated, at the same time the exposure beams are “fired”, leveling and matching data has to be considered in the positioning of the substrate 114, the zone plate array 148, etc.

In an embodiment, the control signals to provide the pattern may be altered to account for factors that may influence the proper supply and/or realization of the pattern on the substrate. For example, a correction may be applied to the control signals to account for the heating of the individually controllable elements 102 and/or zone plate array 148. Such heating may cause changed pointing direction of the individually controllable elements 102 and/or lenses of zone plate array 148, change in uniformity of the radiation from the individually controllable elements 102 and/or lenses of zone plate array 148, etc. In an embodiment, a measured temperature and/or expansion/contraction associated with the individually controllable elements 102 and/or zone plate array 148 from, e.g., a sensor may be used to alter the control signals that would have been otherwise provided to form the pattern. So, for example, during exposure, the temperature of the individually controllable elements 102 and/or zone plate array 148 may vary, the variance causing a change of the projected pattern that would be provided at a single constant temperature. Accordingly, the control signals may be altered to account for such variance. Similarly, in an embodiment, results from the sensor 145 and/or sensor 150 may be used to alter the pattern provided by the individually controllable elements 102. The pattern may be altered to correct, for example, distortion, which may arise from, e.g., optics (if any) between the individually controllable elements 102 and the substrate 114, irregularities in the positioning of the substrate 114, unevenness of the substrate 114, etc.

In an embodiment, the change in the control signals may be determined based on theory of the physical/optical results on the desired pattern arising from the measured parameter (e.g., measured temperature, measured distance by a level sensor, etc.). In an embodiment, the change in the control signals may be determined based on an experimental or empirical model of the physical/optical results on the desired pattern arising from the measured parameter. In an embodiment, the change of the control signals may be applied in a feedforward and/or feedback manner.

FIG. 13 depicts a schematic top view of a lithographic apparatus according to an embodiment for exposing substrates in the manufacture of, for instance, flat panel displays (e.g., LCDs, OLED displays, etc.). Like the lithographic apparatus 100 shown in FIG. 3, the lithographic apparatus 100 comprises a substrate table 106 to hold a flat panel display substrate 114 and a positioning device 116 to move the substrate table 106. The lithographic apparatus 100 further comprises a plurality of patterning devices 104 arranged on a frame 160. In this embodiment, each of the patterning devices 104 comprises a plurality of VCSELs or VECSELs. As shown in FIG. 13, the patterning devices 104 are arranged into a number of separate patterning devices 104, comprising individually addressable elements 102, extending along the X-direction. In an embodiment, the individually addressable elements 102 are substantially stationary, i.e., they do not move significantly during projection. Further, in an embodiment, a number of the zone plate arrays 148 of the patterning devices 104 are staggered from adjacent zone plate arrays 148 in an alternating fashion (see, e.g., FIG. 5). The lithographic apparatus 100 may be arranged to provide pixel-grid imaging.

In operation of the lithographic apparatus 100, a panel display substrate 114 is loaded onto the substrate table 106 using, for example, a robot handler (not shown). The substrate 114 is then displaced in the Y-direction under the frame 160 and the zone plate arrays 148 of the patterning devices 104. The substrate 114 is then exposed to a pattern using the individually addressable elements 102 and the zone plate arrays 148 of the patterning devices 104.

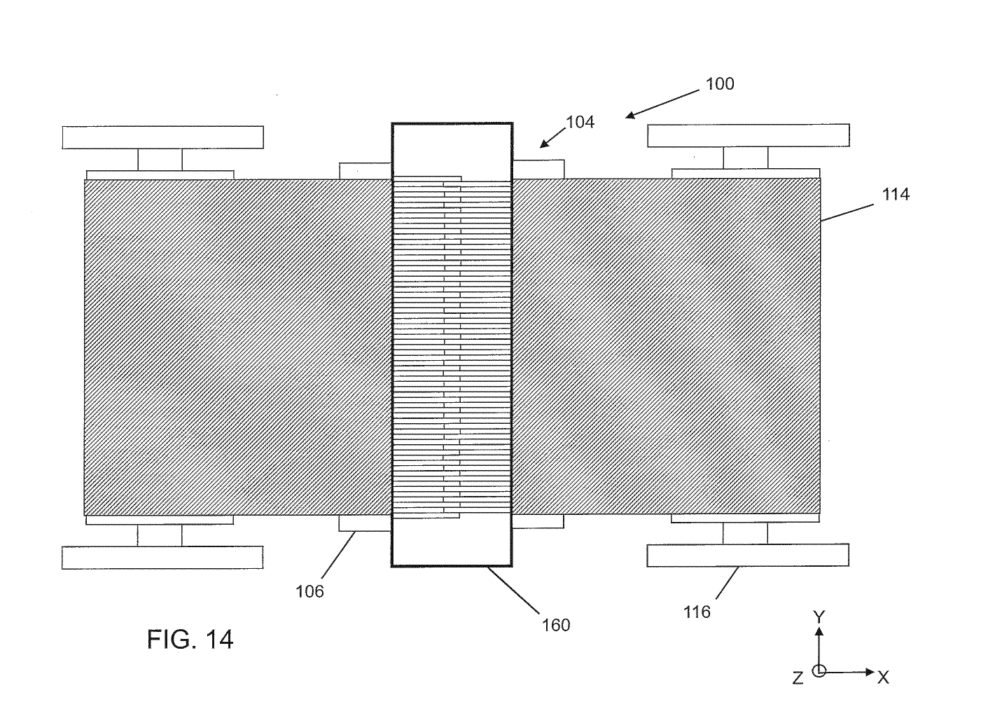

FIG. 14 depicts a schematic top view of a lithographic apparatus according to an embodiment for use with roll-to-roll flexible displays/electronics. Like the lithographic apparatus 100 shown in FIG. 13, the lithographic apparatus 100 comprises a plurality of patterning devices 104 arranged on a frame 160. In this embodiment, each of the patterning devices 104 comprises VECSELs or VCSELs.

The lithographic apparatus may also comprise an object holder having an object table 106 over which a substrate 114 is moved. The substrate 114 is flexible and is rolled onto a roll connected to positioning device 116, which may be a motor to turn the roll. In an embodiment, the substrate 114 may, in addition or alternatively, be rolled from a roll connected to positioning device 116, which may be a motor to turn the roll. In an embodiment, there are at least two rolls, one from which the substrate is rolled and another onto which the substrate is rolled. In an embodiment, object table 106 need not be provided if, for example, substrate 114 is stiff enough between the rolls. In such a case, there would still be an object holder, e.g., one or more rolls. In an embodiment, the lithographic apparatus can provide substrate carrier-less (e.g., carrier-less-foil (CLF)) and/or roll to roll manufacturing. In an embodiment, the lithographic apparatus can provide sheet to sheet manufacturing.

In operation of the lithographic apparatus 100, flexible substrate 114 is rolled onto, and/or from a roll, in the Y-direction under the frame 160 and the patterning devices 104. The substrate 114 is then exposed to a pattern using individually addressable elements 102 and zone plate arrays 148. The individually addressable elements 102 may be operated, for example, to provide pixel-grid imaging as discussed herein.

In an embodiment, frame 160 may comprise a fluid confinement structure configured to maintain a fluid in contact with the substrate to facilitate immersion exposure of the substrate. In an embodiment, the fluid confinement structure may comprise an inlet to provide an immersion fluid (e.g., liquid) to the substrate between the frame 160 and the substrate table. In an embodiment, the fluid confinement structure comprises an outlet to remove the immersion fluid. In an embodiment, the fluid confinement structure comprises a rectangular outlet on the bottom of the frame 160 facing toward the substrate, the rectangular outlet extending the length of the frame 160 in the X-direction and having at least the length of the zone plate arrays 148 in the Y-direction. In the interior of the rectangular outlet, the inlet can provide liquid to fill the rectangular surrounded by the outlet.

The discussion herein has considered mostly 300 mm substrate. For a 450 mm substrate that is exposed full width using the same data-path bandwidth, the productivity for 450 mm substrates would be only 50% lower when measured in WPH as opposed to twice lower for a conventional tool. Also, the footprint increase relative to productivity will be 50% less. The number of patterning devices 104 would likely increase from around 60 to 90 but the same units and the same size data store would still be applicable. The optical bus would require 50% more beam split points, the housing would need to be 150 mm wider and 300 mm deeper but the unit height may still remain around the same value. Given a relatively low unidirectional exposure speed of the substrate stage (1 mm/second) and advanced piezo leveling capability of the individual zone plate arrays 148, stability issues will be much less, or even non-existent, and therefore no substantial stage redesign may be required.

An embodiment may provide one or more advantages selected from the following: (1) maskless technology eliminates use of costly reticles that are time consuming to prepare; (2) a solution that is capable of high bandwidth, relatively low cost, reliable and/or does not require an external light source; (3) a solution that is scalable in productivity (e.g., 10 WPH increments) and robust; (4) zone plate array imaging may enable K1<0.3 without RET or OPC; (5) low cost by using mostly commercial off the shelf materials; (6) relatively low cost of ownership; (7) low maintenance needs; (8) high reliability (less downtime/rework/scrap); (9) small fab footprint per WPH by rack and stack approach; (10) few moving parts; (11) high (e.g., sub-tens of nanometer) positioning accuracy using piezo actuation; (12) low power stable robust VECSEL or VCSEL illumination technology; (13) high imaging quality by use of zone plate array; (14) design may rely much on semiconductor technology, which allows for future technology extension in line with semiconductor progress (i.e., piggy backing on semiconductor improvements); and/or (15) data stream does not require lengthy mathematical recalculation before exposure by using orthogonal square pixel format that allows for a standard lossless bitmap file format, which allows for more fab logistical flexibility.

While embodiments herein have focused on scanning movement of the substrate in the Y-direction, the relative motion between the substrate and the radiation beams may be caused otherwise. For example, the relative motion may be caused movement of the radiation beams relative to the substrate (in a similar fashion as an e-beam apparatus) or by a combination of movement of the beams and substrate.

Although specific reference may be made in this text to the use of a lithographic apparatus in the manufacture of a specific device or structure (e.g. an integrated circuit or a flat panel display), it should be understood that the lithographic apparatus and lithographic method described herein may have other applications. Applications include, but are not limited to, the manufacture of integrated circuits, integrated optical systems, guidance and detection patterns for magnetic domain memories, flat panel displays, LCDs, OLED displays, thin film magnetic heads, micro-electromechanical devices (MEMS), micro-opto-electromechanical systems (MOEMS), DNA chips, packaging (e.g., flip chip, redistribution, etc.), flexible displays or electronics (which are displays or electronics that may be rollable, bendable like paper and remain free of deformities, conformable, rugged, thin, and/or lightweight, e.g., flexible plastic displays), etc. Also, for instance in a flat panel display, the present apparatus and method may be used to assist in the creation of a variety of layers, e.g. a thin film transistor layer and/or a color filter layer. The skilled artisan will appreciate that, in the context of such alternative applications, any use of the terms “wafer” or “die” herein may be considered as synonymous with the more general terms “substrate” or “target portion,” respectively. The substrate referred to herein may be processed, before or after exposure, in for example a track (e.g., a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

A flat panel display substrate may be rectangular in shape. A lithographic apparatus designed to expose a substrate of this type may provide an exposure region which covers a full width of the rectangular substrate, or which covers a portion of the width (for example half of the width). The substrate may be scanned underneath the exposure region, while the patterning device is synchronously scanned through the patterned beam or the patterning device provides a varying pattern. In this way, all or part of the desired pattern is transferred to the substrate. If the exposure region covers the full width of the substrate then exposure may be completed with a single scan. If the exposure region covers, for example, half of the width of the substrate, then the substrate may be moved transversely after the first scan, and a further scan is typically performed to expose the remainder of the substrate.

The term “patterning device”, used herein should be broadly interpreted as referring to any device that can be used to modulate the cross-section of a radiation beam such as to create a pattern in (part of) the substrate. It should be noted that the pattern imparted to the radiation beam may not exactly correspond to the desired pattern in the target portion of the substrate, for example if the pattern includes phase-shifting features or so called assist features. Similarly, the pattern eventually generated on the substrate may not correspond to the pattern formed at any one instant by the array of individually controllable elements. This may be the case in an arrangement in which the eventual pattern formed on each part of the substrate is built up over a given period of time or a given number of exposures during which the pattern provided by the array of individually controllable elements and/or the relative position of the substrate changes. Generally, the pattern created on the target portion of the substrate will correspond to a particular functional layer in a device being created in the target portion, e.g., an integrated circuit or a flat panel display (e.g., a color filter layer in a flat panel display or a thin film transistor layer in a flat panel display). Examples of such patterning devices include, e.g., programmable mirror arrays, laser diode arrays, light emitting diode arrays, grating light valves, and LCD arrays. Patterning devices whose pattern is programmable with the aid of an electronic device (e.g., a computer), e.g., patterning devices comprising a plurality of programmable elements that can each modulate the intensity of a portion of the radiation beam, including electronically programmable patterning devices having a plurality of programmable elements that impart a pattern to the radiation beam by modulating the phase of a portion of the radiation beam relative to adjacent portions of the radiation beam, are collectively referred to herein as “contrast devices”. In an embodiment, the patterning device comprises at least 10 programmable elements, e.g. at least 100, at least 200, at least 500, or at least 1000 programmable elements. Embodiments of several of these devices are discussed in some more detail below:
A programmable mirror array. The programmable mirror array may comprise a matrix-addressable surface having a viscoelastic control layer and a reflective surface. The basic principle behind such an apparatus is that, for example, addressed areas of the reflective surface reflect incident radiation as diffracted radiation, whereas unaddressed areas reflect incident radiation as undiffracted radiation. Using an appropriate spatial filter, the undiffracted radiation can be filtered out of the reflected beam, leaving only the diffracted radiation to reach the substrate. In this manner, the beam becomes patterned according to the addressing pattern of the matrix-addressable surface. It will be appreciated that, as an alternative, the filter may filter out the diffracted radiation, leaving the undiffracted radiation to reach the substrate. An array of diffractive optical MEMS devices may also be used in a corresponding manner. A diffractive optical MEMS device may comprise a plurality of reflective ribbons that may be deformed relative to one another to form a grating that reflects incident radiation as diffracted radiation. A further embodiment of a programmable mirror array employs a matrix arrangement of tiny mirrors, each of which may be individually tilted about an axis by applying a suitable localized electric field, or by employing piezoelectric actuation means. The degree of tilt defines the state of each mirror. The mirrors are controllable, when the element is not defective, by appropriate control signals from the controller. Each non-defective element is controllable to adopt any one of a series of states, so as to adjust the intensity of its corresponding pixel in the projected radiation pattern. Once again, the mirrors are matrix-addressable, such that addressed mirrors reflect an incoming radiation beam in a different direction to unaddressed mirrors; in this manner, the reflected beam may be patterned according to the addressing pattern of the matrix-addressable mirrors. The required matrix addressing may be performed using suitable electronic means. More information on mirror arrays as here referred to can be gleaned, for example, from U.S. Pat. Nos. 5,296,891 and 5,523,193, and PCT Patent Application Publication Nos. WO 98/38597 and WO 98/33096, which are incorporated herein by reference in their entirety.
A programmable LCD array. An example of such a construction is given in U.S. Pat. No. 5,229,872, which is incorporated herein by reference in its entirety.

The lithographic apparatus may comprise one or more patterning devices, e.g. one or more contrast devices. For example, it may have a plurality of arrays of individually controllable elements, each controlled independently of each other. In such an arrangement, some or all of the arrays of individually controllable elements may have at least one of a common illumination system (or part of an illumination system), a common support structure for the arrays of individually controllable elements and/or a common projection system (or part of the projection system).

It should be appreciated that where pre-biasing of features, optical proximity correction features, phase variation techniques and/or multiple exposure techniques are used, for example, the pattern “displayed” by the array of individually controllable elements may differ substantially from the pattern eventually transferred to a layer of or on the substrate. Similarly, the pattern eventually generated on the substrate may not correspond to the pattern formed at any one instant by the array of individually controllable elements. This may be the case in an arrangement in which the eventual pattern formed on each part of the substrate is built up over a given period of time or a given number of exposures during which the pattern of the array of individually controllable elements and/or the relative position of the substrate changes.

The projection system and/or illumination system may include various types of optical components, e.g., refractive, reflective, magnetic, electromagnetic, electrostatic or other types of optical components, or any combination thereof, to direct, shape, or control the beam of radiation.

In the description, the term “lens” should be understood generally to encompass any refractive, reflective, and/or diffractive optical element that provides the same function as the referenced lens. For example, an imaging lens may be embodied in the form of a conventional refractive lens having optical power, in the form of a Schwarzschild reflective system having optical power, and/or in the form of a zone plate having optical power. Moreover, an imaging lens may comprise non-imaging optics if the resulting effect is to produce a converged beam on the substrate.

The lithographic apparatus may be of a type having two (e.g., dual stage) or more substrate tables (and/or two or more patterning device tables). In such “multiple stage” machines the additional table(s) may be used in parallel, or preparatory steps may be carried out on one or more tables while one or more other tables are being used for exposure.

The lithographic apparatus may also be of a type wherein at least a portion of the substrate may be covered by an “immersion liquid” having a relatively high refractive index, e.g. water, so as to fill a space between the projection system and the substrate. An immersion liquid may also be applied to other spaces in the lithographic apparatus, for example, between the patterning device and the projection system. Immersion techniques are used to increase the NA of projection system. The term “immersion” as used herein does not mean that a structure, e.g., a substrate, must be submerged in liquid, but rather only means that liquid is located between the projection system and the substrate during exposure.

Further, the apparatus may be provided with a fluid processing cell to allow interactions between a fluid and irradiated parts of the substrate (e.g., to selectively attach chemicals to the substrate or to selectively modify the surface structure of the substrate).

In an embodiment, the substrate has a substantially circular shape, optionally with a notch and/or a flattened edge along part of its perimeter. In an embodiment, the substrate has a polygonal shape, e.g. a rectangular shape. Embodiments where the substrate has a substantially circular shape include embodiments where the substrate has a diameter of at least 25 mm, for instance at least 50 mm, at least 75 mm, at least 100 mm, at least 125 mm, at least 150 mm, at least 175 mm, at least 200 mm, at least 250 mm, or at least 300 mm. In an embodiment, the substrate has a diameter of at most 500 mm, at most 400 mm, at most 350 mm, at most 300 mm, at most 250 mm, at most 200 mm, at most 150 mm, at most 100 mm, or at most 75 mm. Embodiments where the substrate is polygonal, e.g. rectangular, include embodiments where at least one side, e.g. at least 2 sides or at least 3 sides, of the substrate has a length of at least 5 cm, e.g. at least 25 cm, at least 50 cm, at least 100 cm, at least 150 cm, at least 200 cm, or at least 250 cm. In an embodiment, at least one side of the substrate has a length of at most 1000 cm, e.g. at most 750 cm, at most 500 cm, at most 350 cm, at most 250 cm, at most 150 cm, or at most 75 cm. In an embodiment, the substrate is a rectangular substrate having a length of about 250-350 cm and a width of about 250-300 cm The thickness of the substrate may vary and, to an extent, may depend, e.g., on the substrate material and/or the substrate dimensions. In an embodiment, the thickness is at least 50 μm, for instance at least 100 μm, at least 200 μm, at least 300 μm, at least 400 μm, at least 500 μm, or at least 600 μm. In one embodiment, the thickness of the substrate is at most 5000 μm, for instance at most 3500 μm, at most 2500 μm, at most 1750 μm, at most 1250 μm, at most 1000 μm, at most 800 μm, at most 600 μm, at most 500 μm, at most 400 μm, or at most 300 μm. The substrate referred to herein may be processed, before or after exposure, in for example a track (a tool that typically applies a layer of resist to a substrate and develops the exposed resist). Properties of the substrate may be measured before or after exposure, for example in a metrology tool and/or an inspection tool.

In an embodiment, a resist layer is provided on the substrate. In an embodiment, the substrate is a wafer, for instance a semiconductor wafer. In an embodiment, the wafer material is selected from the group consisting of Si, SiGe, SiGeC, SiC, Ge, GaAs, InP, and InAs. In an embodiment, the wafer is a III/V compound semiconductor wafer. In an embodiment, the wafer is a silicon wafer. In an embodiment, the substrate is a ceramic substrate. In an embodiment, the substrate is a glass substrate. Glass substrates may be useful, e.g., in the manufacture of flat panel displays and liquid crystal display panels. In an embodiment, the substrate is a plastic substrate. In an embodiment, the substrate is transparent (for the naked human eye). In an embodiment, the substrate is colored. In an embodiment, the substrate is absent a color.

While, in an embodiment, the patterning device 104 is described and/or depicted as being above the substrate 114, it may instead or additionally be located under the substrate 114. Further, in an embodiment, the patterning device 104 and the substrate 114 may be side by side, e.g., the patterning device 104 and substrate 114 extend vertically and the pattern is projected horizontally. In an embodiment, a patterning device 104 is provided to expose at least two opposite sides of a substrate 114. For example, there may be at least two patterning devices 104, at least on each respective opposing side of the substrate 114, to expose those sides. In an embodiment, there may be a single patterning device 104 to project one side of the substrate 114 and appropriate optics (e.g., beam directing mirrors) to project a pattern from the single patterning device 104 onto another side of the substrate 114.

While specific embodiments have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

Moreover, although this invention has been disclosed in the context of certain embodiments and examples, it will be understood by those skilled in the art that the present invention extends beyond the specifically disclosed embodiments to other alternative embodiments and/or uses and obvious modifications and equivalents thereof. In addition, while a number of variations have been shown and described in detail, other modifications, which are within the scope of this invention, will be readily apparent to those of skill in the art based upon this disclosure. For example, it is contemplated that various combination or sub-combinations of the specific features and aspects of the embodiments may be made and still fall within the scope of the invention. Accordingly, it should be understood that various features and aspects of the disclosed embodiments can be combined with or substituted for one another in order to form varying modes of the disclosed invention.

Thus, while various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

1. A lithographic apparatus comprising:
a substrate holder constructed to hold a substrate;
a modulator configured to expose an exposure area of the substrate to a plurality of beams modulated according to a desired pattern, the modulator comprising a plurality of VECSELs or VCSELs to provide the plurality of beams; and
a projection system configured to project the modulated beams onto the substrate.

2. The apparatus of claim 1, wherein the projection system comprises an array of lenses to receive the plurality of beams.

3. The apparatus of claim 2, wherein the array of lenses is a zone plate array.

4. The apparatus of claim 2, wherein the array of lenses is arranged in a two-dimensional array where the lenses are arranged in a triangular layout.

5. The apparatus of claim 2, further comprising an actuator to cause the array of lenses to move with respect to the plurality of VECSELs or VCSELs during exposure of the exposure area.

6. The apparatus of claim 5, further comprising a controller configured to oscillate the array of lenses in a Lissajous pattern.

7. The apparatus of claim 5, further comprising a positioning device to cause the actuator and the array of lenses to move with respect to the substrate.

8. The apparatus of claim 5, comprising a structure having the lenses and a frame surrounding the structure, the frame comprising a mount to movably connect the structure to the frame.

9. The apparatus of claim 8, wherein the actuator is configured to displace the structure with respect to the frame.

10.-19. (canceled)

20. A lithographic system, comprising a plurality of lithographic apparatuses, at least one lithographic apparatus of the plurality of lithographic apparatuses being arranged above another lithographic apparatus of the plurality of lithographic apparatuses.

21. The system of claim 20, further comprising a rack having a plurality of openings into which the plurality of lithographic apparatuses are removably provided.

22. The system of claim 21, wherein the rack comprises a two-dimensional array of openings.

23. The system of claim 22, wherein the rack comprises at least two horizontal rows of openings and at least two vertical columns of openings.

24. The system of claim 20, wherein an opening of each of the plurality of lithographic apparatuses is in a substantially same plane and the system further comprises a robot configured to supply a substrate to the openings.

25. The system of claim 24, further comprising a measurement apparatus separate from the plurality of lithographic apparatuses, an opening of the measurement apparatus being in the substantially same plane as the openings of the lithographic apparatuses or in a plane coplanar thereto.

26. The system of claim 20, further comprising a plurality of measurement apparatuses separate from the plurality of lithographic apparatuses.

27. The system of claim 20, wherein each of the lithographic apparatus is substantially identical in construction and size.

28. The system of claim 20, wherein each of the lithographic apparatus operates independently from each other.

29. A zone plate array arrangement comprising lenses arranged in a two-dimensional array where the lenses are arranged in a triangular layout.

30.-32. (canceled)

33. A device manufacturing method, comprising:
modulating a plurality of beams according to a desired pattern using a plurality of VECSELs or VCSELs that provide the plurality of beams; and
projecting the modulated beams onto an exposure area of a substrate.

34.-42. (canceled)
